(19) United States
(12) Patent Application Publication
(10) Pub. No.: US 2025/0300098 A1
(43) Pub. Date: Sep. 25, 2025

(54) MANAGING PROTECTION STRUCTURES IN SEMICONDUCTOR DEVICES

(71) Applicant: Yangtze Memory Technologies Co., Ltd., Wuhan (CN)

(72) Inventors: Huiwen LIU, Wuhan (CN); Yuhui HAN, Wuhan (CN); Wei YUAN, Wuhan (CN); Kun ZHANG, Wuhan (CN); Wenxi ZHOU, Wuhan (CN); Zhiliang XIA, Wuhan (CN)

(21) Appl. No.: 18/783,202

(22) Filed: Jul. 24, 2024

Related U.S. Application Data
(63) Continuation of application No. PCT/CN2024/083249, filed on Mar. 22, 2024.

(51) Int. Cl. H01L 23/58; H01L 21/768; H01L 23/00; H10B 43/27; H10B 43/40

(52) U.S. Cl. CPC H01L 23/585; H01L 21/76816; H01L 23/562; H10B 43/27; H10B 43/40

(57) ABSTRACT

The present disclosure relates to methods, devices, systems, and techniques for managing protection structures in semiconductor devices. An example semiconductor device includes at least one array region, at least one connection region, and a protection structure surrounding the at least one array region and the at least one connection region. The protection structure has a surface including a series of curved portions connected together.

### CROSS-REFERENCE TO RELATED APPLICATIONS

This application is a continuation of International Application No. PCT/CN2024/083249, filed on Mar. 22, 2024, the disclosure of which is hereby incorporated by reference in its entirety.

### TECHNICAL FIELD

The present disclosure relates to semiconductor devices and fabrication methods thereof.

### BACKGROUND

Semiconductor devices, e.g., memory devices, can have various structures to increase a density of memory cells and lines on a chip. For example, three-dimensional (3D) memory devices are attractive due to their capability to increase an array density by stacking more layers within a similar footprint. A 3D memory device normally includes a memory array of memory cells and peripheral circuits for facilitating operations of the memory array.

### SUMMARY

The present disclosure describes methods, devices, systems, and techniques for managing protection structures in semiconductor devices.

One aspect of the present disclosure features a semiconductor device. The semiconductor device includes at least one array region, at least one connection region, and a protection structure surrounding the at least one array region and the at least one connection region. The protection structure has a surface including a series of curved portions connected together.

In some implementations, the surface is non-flat and includes a wave-like surface or a caterpillar-like surface.

In some implementations, the protection structure extends along a first direction, and the at least one array region is adjacent to the at least one connection region in a second direction perpendicular to the first direction. The semiconductor device includes a stack of conductive layers and insulating layers alternating with each other along the first direction.

In some implementations, the conductive layers and the insulating layers in the stack are located along the first direction within a range defined by a length of the protection structure along the first direction.

In some implementations, the protection structure extends from a first side of the semiconductor device to a second side the semiconductor device along the first direction, the first side and the second side being opposite to each other along the first direction.

In some implementations, the protection structure includes segments that are connected and enclose the at least one array region and the at least one connection region in a plane perpendicular to the first direction.

In some implementations, the segments include a first segment and a second segment that each extend along the second direction and a third segment and a fourth segment that each extend along a third direction perpendicular to the first direction and the second direction.

In some implementations, a cross section of at least one of the segments has a shape of partial circles arranged in a line and connected together, and the cross section is perpendicular to the first direction.

In some implementations, the protection structure includes dielectric portions and a conductive portion between the dielectric portions. The conductive portion is in contact with the dielectric portions. At least one of the dielectric portions includes the surface.

In some implementations, the dielectric portions include silicon oxide, and the conductive portion includes a metal material.

In some implementations, the conductive portion is a solid metal structure.

In some implementations, the semiconductor device further includes a gate line structure, channel structures, and a semiconductor layer connected to the gate line structure and the channel structures. The conductive portion of the protection structure includes a conductive structure exposed from a surface of the semiconductor device. The conductive structure is isolated from the semiconductor layer by a dielectric material.

In some implementations, the gate line structure includes a first segment extending along the second direction.

In some implementations, the gate line structure further includes a second segment extending along a third direction perpendicular to the first direction and the second direction. The first segment of the gate line structure is connected to the second segment of the gate line structure.

In some implementations, the protection structure extends along a first direction, and the at least one array region is adjacent to the at least one connection region in a second direction perpendicular to the first direction, and along the first direction, the semiconductor layer is separated from the surface of the semiconductor device with the dielectric material.

Another aspect of the present disclosure features a method including providing a semiconductor structure including at least one array region and at least one connection region. The method further includes forming a seal ring structure surrounding the at least one array region and the at least one connection region, where the seal ring structure has a surface including a series of curved portions connected together.

In some implementations, providing the semiconductor structure includes providing the semiconductor structure including a substrate and a stack of sacrificial layers and insulating layers alternating with each other along a first direction. Forming the seal ring structure includes forming gate line holes, channel holes, and seal ring holes extending through the stack and into the substrate along the first direction, where the seal ring holes surround the gate line holes and the channel holes. Forming the seal ring structure further includes forming seal ring trenches and one or more gate line trenches by expanding the seal ring holes and the gate line holes, where the seal ring trenches are connected and enclose the one or more gate line trenches. Forming the seal ring structure further includes forming the seal ring structure in the connected seal ring trenches, where the surface of the seal ring structure is non-flat.

In some implementations, the stack includes one or more decks. The gate line holes, the channel holes, and the seal ring holes in at least one of the one or more decks are formed by a same etching process.

In some implementations, the gate line holes include one or more groups of gate line holes. Each group of the one or more groups of gate line holes are arranged along a second direction perpendicular to the first direction or a third direction perpendicular to the first direction and the second direction. The seal ring holes include groups of seal ring holes. Each group of the groups of seal ring holes are arranged along the second direction or the third direction.

In some implementations, one of the one or more gate line trenches includes expanded gate line holes formed from a corresponding group of the one or more groups of gate line holes, and the expanded gate line holes are connected with each other along a corresponding one of the second direction and the third direction. One of the seal ring trenches includes expanded seal ring holes formed from a corresponding group of the groups of seal ring holes, and the expanded seal ring holes are connected with each other along a corresponding one of the second direction and the third direction.

In some implementations, one of the expanded seal ring holes includes a body portion above the substrate and a bottom portion in the substrate; and a size of a cross section of the bottom portion is smaller than a size of a cross section of the body portion.

In some implementations, the method further includes forming channel structures in the channel holes, forming conductive layers between the insulating layers by depositing at least one conductive material into the one or more gate line trenches; and forming one or more gate line structures in the one or more gate line trenches.

In some implementations, forming the seal ring structure in the connected seal ring trenches includes forming a first dielectric portion, a second dielectric portion, and a dielectric bottom layer in the connected seal ring trenches by depositing a dielectric material into the connected seal ring trenches. The first dielectric portion is in contact with a first sidewall of the connected seal ring trenches, the second dielectric portion is in contact with a second sidewall of the connected seal ring trenches, the dielectric bottom layer is in contact with a bottom of the connected seal ring trenches, and the first dielectric portion is connected to the second dielectric portion by the dielectric bottom layer. In some implementations, forming the seal ring structure in the connected seal ring trenches includes forming a conductive portion by filling a conductive material between the first dielectric portion and the second dielectric portion.

In some implementations, the semiconductor structure further includes a polysilicon layer between the stack and the substrate. A bottom of the conductive portion is above the polysilicon layer along the first direction.

In some implementations, the method further includes removing the substrate and the dielectric bottom layer. The method further includes forming a conductive structure connected to the conductive portion. The conductive structure is exposed from a surface of the semiconductor structure. The method further includes forming a semiconductor layer connected to the one or more gate line structures and the channel structures, where the semiconductor layer includes a polysilicon material.

A further aspect of the present disclosure features a memory system. The memory system includes a memory device and a memory controller coupled to the memory device and configured to control the memory device. The memory device includes at least one array region, at least one connection region, and a protection structure surrounding the at least one array region and the at least one connection region. The protection structure has a surface including a series of curved portions connected together.

The details of one or more implementations of the subject matter of this present disclosure are set forth in the accompanying drawings and the description below. Other features, aspects, and advantages of the subject matter will become apparent from the description, the drawings, and the claims.

### BRIEF DESCRIPTION OF THE DRAWINGS

The accompanying drawings, which are incorporated herein and form a part of the present disclosure, illustrate aspects of the present disclosure and, together with the description, further serve to explain the principles of the present disclosure and to enable a person of ordinary skill in the pertinent art to make and use the present disclosure.

FIG. 1 illustrates an example wafer including semiconductor devices each having a protection structure.

FIGS. 2A-2D illustrate example semiconductor devices.

FIGS. 3A-1 to 3P illustrate an example process of manufacturing a semiconductor device.

FIG. 4 illustrates a flow chart of an example process of manufacturing a semiconductor device.

FIG. 5 illustrates a block diagram of an example system.

Like reference numbers and designations in the various drawings indicate like elements. It is also to be understood that the various exemplary implementations shown in the figures are merely illustrative representations and are not necessarily drawn to scale.

### DETAILED DESCRIPTION

Due to a demand for cheaper memory devices with a higher-density, a memory device (e.g., a 3D NAND flash memory) can be formed to have multiple decks, and each deck can have a large number of layers. The large number of layers and the high aspect ratio of such memory device may bring challenges to the manufacturing process. For example, stress issues can become more severe and cause X-Y bow problem in word line filling (e.g., conductive layers bending in the X direction and/or the Y direction). In another example, components with high aspect ratios in the memory device (e.g., gate line structures and memory blocks) may tilt, shift, or even collapse during the manufacturing process. Furthermore, the increase in depth of the memory device may introduce or exacerbate overlay (OVL) issues in the manufacturing process.

Implementations of the present disclosure provide example techniques for managing protection structures in semiconductor devices. The protection structures can be formed in semiconductor devices, for preventing various types of damages, such as electrostatic discharge (ESD), oxygen, moisture, and mechanical damages. The protection structures can include seal rings, which can play an important role in preventing mechanical damage during chip cutting and can effectively separate dies and release stress. In some implementations, channel holes and gate line holes can be formed in a same etching process using a same etching mask, which can be referred to as channel hole and gate line hole merging. Seal ring profiles that are not compatible with the channel hole and gate line hole merging may cause tungsten (W) loss in the fabrication, thereby affecting the protection provided by the seal rings and leading to reduced process reliability. Seal ring designs that are compatible with the channel hole and gate line hole merging and can solve the aforementioned issues are desirable.

In some implementations, an example semiconductor device includes at least one array region, at least one connection region, and a seal ring surrounding the at least one array region and the at least one connection region. In some implementations, seal ring holes, channel holes, and gate line holes can be formed in a same etching process, which enable the seal ring holes to be compatible with the channel hole and the gate line merging. The seal ring holes can be expanded and connected with one another. The seal ring can be formed in the expanded seal ring holes. The seal ring can have at least one surface including a series of curved portions connected together.

Implementations of the present disclosure can provide one or more of the following technical advantages and/or benefits. Seal ring holes, channel holes, and gate line holes can be formed in a same etching process using a same etching mask, thereby improving the manufacturing process flow and reducing the fabrication costs. In addition, an overlay (OVL) shift problem can be resolved, and the process window can be enlarged. The techniques allow forming a seal ring to separate dies before forming the word lines, thereby effectively releasing stress during the manufacturing process. Further, forming the seal ring in the expanded seal ring holes can provide seal rings with profiles that solve the W loss issue, thereby improving the production yield and the reliability of the semiconductor device. Therefore, the fabrication cost of the semiconductor device can be reduced, and a storage capacity per unit area of the semiconductor device can be increased.

The techniques can be applied to various types of semiconductor devices, volatile memory devices, such as DRAM memory devices, or non-volatile memory (NVM) devices, such as NAND flash memory, NOR flash memory, resistive random-access memory (RRAM), phase-change memory (PCM) such as phase-change random-access memory (PCRAM), spin-transfer torque (STT)-Magnetoresistive random-access memory (MRAM), among others. The techniques can also be applied to charge-trapping based memory devices, e.g., silicon-oxide-nitride-oxide-silicon (SONOS) memory devices, and floating-gate based memory devices. The techniques can be applied to three-dimensional (3D) memory devices. The techniques can be applied to various memory types, such as SLC (single-level cell) devices, MLC (multi-level cell) devices like 2-level cell devices, TLC (triple-level cell) devices, QLC (quad-level cell) devices, or PLC (penta-level cell) devices. Additionally or alternatively, the techniques can be applied to various types of devices and systems, such as secure digital (SD) cards, embedded multimedia cards (eMMC), or solid-state drives (SSDs), embedded systems, among others.

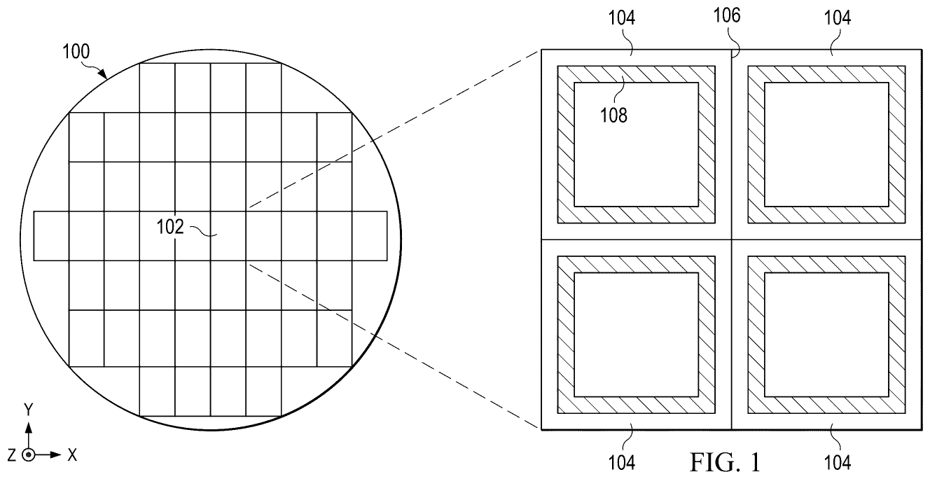

FIG. 1 illustrates a top view of an example wafer 100 including semiconductor devices 104 each having a protection structure 108. Wafer 100 includes multiple shots 102 each including multiple dies (e.g., four dies as illustrated in FIG. 1), referred to herein as semiconductor devices 104, separated by scribe lines 106. As shown in FIG. 1, each semiconductor device 104 is adjacent to a first semiconductor device 104 in a first direction (e.g., the X direction) and adjacent to a second semiconductor device 104 in a second direction (e.g., the Y direction) perpendicular to the first direction. Each semiconductor device 104 includes a protection structure 108 for protecting the semiconductor devices from damages, such as ESD, oxygen, moisture, and mechanical damages. In some implementations, the protection structures (e.g., the protection structure 108 of FIG. 1) also can be referred to as seal rings.

It is noted that X, Y, and Z axes (also referred to as X, Y, and Z directions) are included in FIG. 1 to further illustrate the spatial relationship of various components in a semiconductor device. A substrate of the semiconductor device can include two lateral surfaces extending laterally in the X-Y plane: a top surface on the front side of the substrate on which a component of the semiconductor device can be formed, and a bottom surface on the backside opposite to the front side of the substrate. The Z direction is perpendicular to both the X and Y directions. As used herein, whether one component (e.g., a layer or a device) is “on,” “above,” or “below” another component (e.g., a layer or a device) of the semiconductor device is determined relative to the substrate of the semiconductor device in the Z direction (the vertical direction perpendicular to the X-Y plane, e.g., the thickness direction of the substrate) when the substrate is positioned in the lowest plane of the semiconductor device in the Z direction. The same notion for describing the spatial relationships is applied throughout the present disclosure.

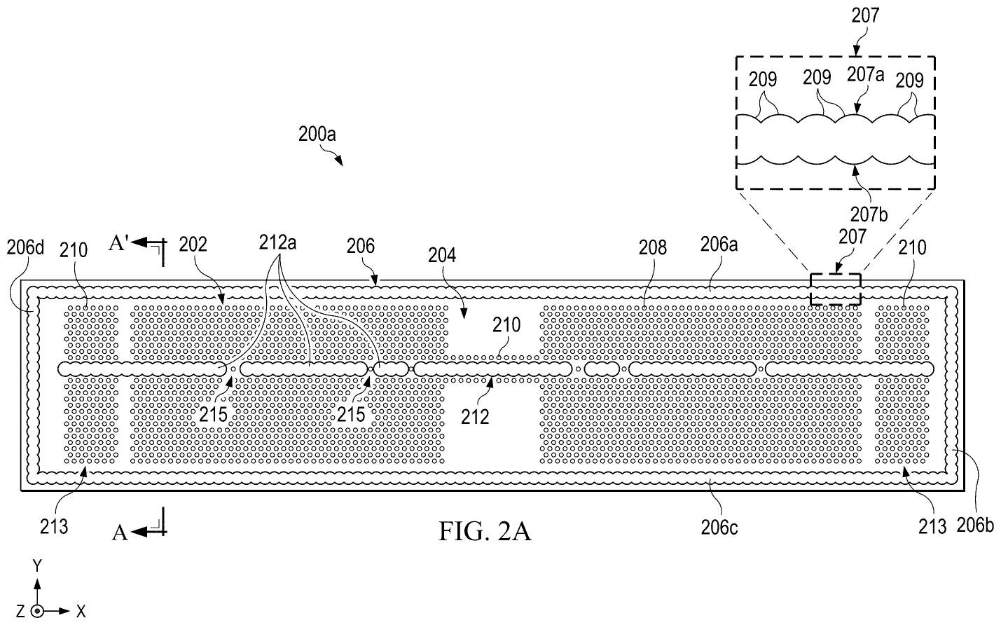

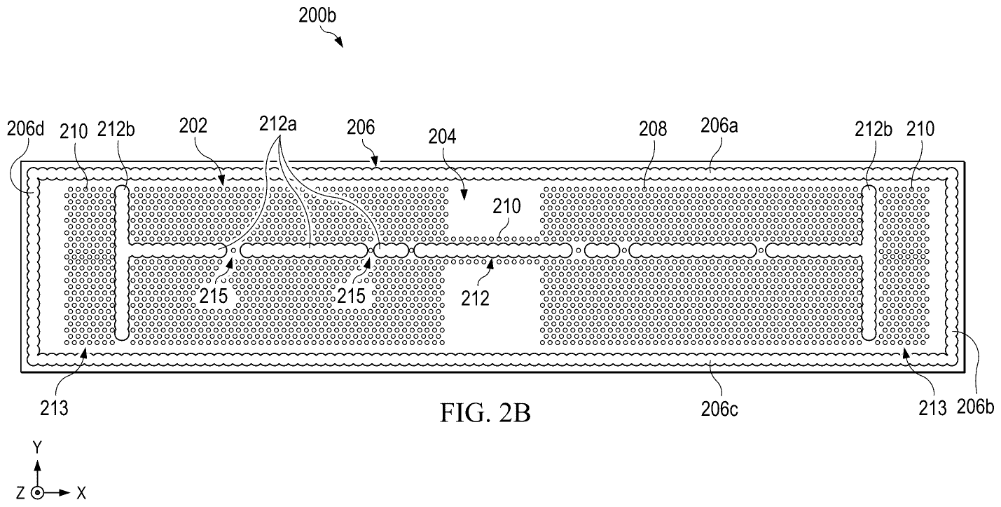

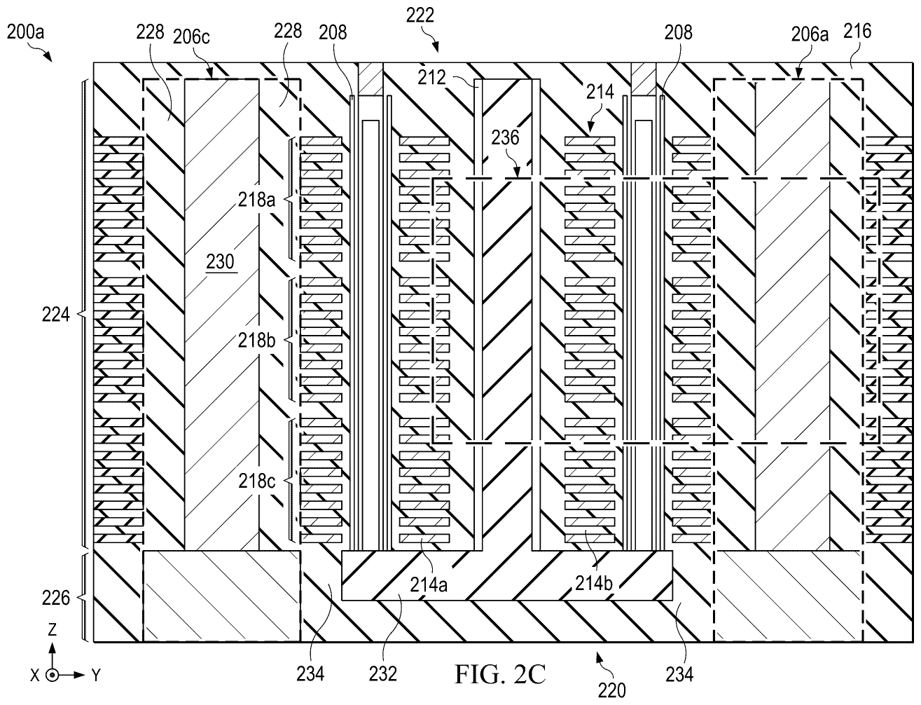

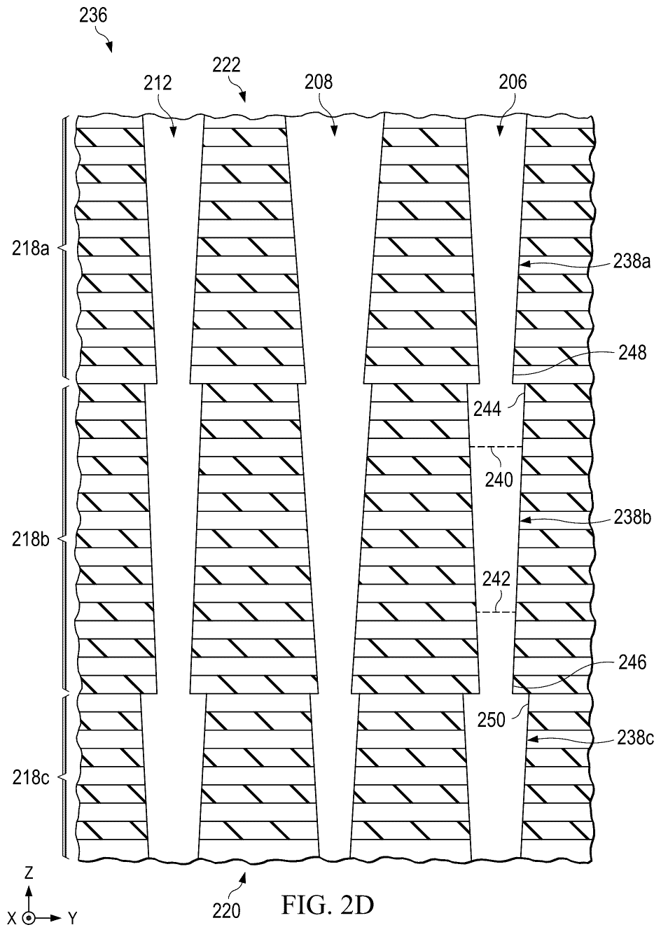

FIG. 2A illustrates a top view of an example semiconductor device 200a having a protection structure (e.g., a seal ring). The semiconductor device 200a can be an example of the semiconductor device 104 in FIG. 1. In some implementations, the semiconductor device 200a can be a memory device, such as a three-dimensional (3D) NAND memory device. The semiconductor device 200a can include one or more array regions and one or more connection regions configured to provide conductive connections for the one or more array regions. In some implementations, as shown in FIG. 2A, the semiconductor device 200a includes two array regions 202 and a connection region 204 between the two array regions 202 along a first horizontal direction (e.g., the X direction). The semiconductor device 200a can further include a seal ring 206 surrounding the array regions 202 and the connection region 204 in a horizontal plane (e.g., the X-Y plane). The seal ring 206 can be an example of the protection structure 108 of FIG. 1. Each array region 202 can include an array of channel structures 208. Each channel structure 208 can be used to form a string of memory cells coupled in serial along a vertical direction (e.g., Z direction) perpendicular to the first horizontal direction. In some implementations, the connection region 204 can include a staircase structure (not shown) and an array of contact structures (not shown) formed on the staircase structure. In some other implementations, conductive layers (e.g., conductive layers 214A in FIG. 2C as described below) in the connection region 204 can form a structure different from a staircase structure. For example, a contact structure can be connected to a corresponding conductive layer and can extend through other conductive layers, and spacer for insulation can be formed between the contact structure and the other conductive layers. In some implementations, the array regions 202 and the connection region 204 can include dummy channel structures 210 (also referred to as dummy memory strings) for process variation control during fabrication and/or for additional mechanical support. In some implementations, the dummy channel structures 210 can be in one or more dummy regions or peripheral regions (e.g., regions 213 as shown in FIG. 2A). In some examples, the dummy regions 213 can be separated from the array regions 202 and can also be surrounded by the seal ring 206 in the horizontal plane. It is understood that the example in FIG. 2A is for illustration purpose and is not intended to be construed in a limiting sense. In practice, any suitable arrangement of various regions in the semiconductor device 200a can be applied. In some instances, the semiconductor device 200a can have two connection regions 204 arranged along the X direction and an array region 202 between the two connection regions 204 along the X direction.

In some implementations, the semiconductor device 200a can include one or more gate line structures 212. The gate line structure 212 can extend in the X direction and can divide an array region into multiple memory blocks. In some implementations, the gate line structure 212 can function as a common source contact for the channel structures 208 in the array regions 202. As shown in FIG. 2A, the gate line structure 212 can include multiple portions (also referred to as segments) 212a extending along the X direction. The multiple portions 212a can be separated and spaced by isolating structures 215 along the X direction. The isolating structures 215 can eliminate or reduce stress built in the gate line structure 212 during the manufacturing process, thereby preventing the gate line structure 212 from bending or cracking. In some implementations, as illustrated by another example semiconductor device 200b in FIG. 2B, the gate line structure 212 can further include multiple portions 212b extending along the Y direction. As shown in FIG. 2B, one portion 212b can be connected to another portion 212a to form a T shape, and the gate line structure 212 that includes one portion 212a and two portions 212b can be in an H shape.

In some implementations, the seal ring 206 can include segments that are connected and enclose the array regions 202 and the connection region 204 in the X-Y plane. For example, as shown in FIG. 2A, the seal ring 206 includes segments 206a, 206b, 206c, and 206d connected together. The segments 206a and 206c extend along the X direction, and the segments 206b and 206d extend along the Y direction. While the seal ring 206 illustrated in FIG. 2A has four segments forming a rectangle shape, it is understood that, in other examples, the seal ring 206 can have any suitable number of segments and can have any other suitable shapes (e.g., square, circle, or oval).

FIG. 2A further illustrates an enlarged view of a portion 207 of the segment 206a of the seal ring 206. As shown in the enlarged view, the seal ring 206 can have at least two non-flat surfaces 207a and 207b opposite to each other (e.g., along the X direction or the Y direction). Each of the two surfaces 207a and 207b includes a series of curved portions connected together. For example, the surface 207a includes curved portions 209 connected with one another along the X direction. In other words, the surfaces 207a and 207b are wave-like or caterpillar-like. In some implementations, a cross section of the portion 207 has a shape of partial circles arranged in a line and connected together. The cross section of the portion 207 is in the X-Y plane (e.g., perpendicular to the vertical direction).

FIG. 2C illustrates a cross-sectional view of the semiconductor device 200a along a cut line AA′ of FIG. 2A. The semiconductor device 200a can include a stack 214 of alternating conductive layers 214A and insulating layers 214B. The semiconductor device 200a can include a top layer 216 made of an isolating material (e.g., oxide). The stack 214 can extend in a second horizontal direction (e.g., Y direction) perpendicular to the first horizontal direction. The conductive layers 214A and the insulating layers 214B can alternate in the vertical direction (e.g., Z direction) perpendicular to the second horizontal direction. The conductive layers 214A can be the same or different from each other in thickness, for example, ranging from 10-500 nm, e.g., about 35 nm. The insulating layers 214B can also be the same or different from each other in thickness, for example, ranging from 10-500 nm, e.g., about 25 nm. It should be noted that the number of the conductive layers 214A and the insulating layers 214B shown in FIG. 2C is for illustration only and that any suitable number of conductive layers and insulating layers can be included in the stack 214. In some implementations, the stack 214 can include multiple decks (e.g., decks 218a, 218b, and 218c as shown in FIG. 2C) stacked along the vertical direction (e.g., the Z direction). Each of the multiple decks can include a subset of the conductive layers 214A and the insulating layers 214B in the stack 214. The conductive layers 214A can include any suitable conducting material, such as tungsten (W), cobalt (Co), copper (Cu), aluminum (Al), titanium nitride (TiN), polycrystalline silicon (polysilicon), doped silicon, silicides, or any combination thereof. The insulating layers 214B can include a dielectric material, such as silicon oxide, silicon nitride, silicon oxynitride, or any combination thereof. In some implementations, the insulating layers 214B can also include high-K dielectric materials, such as hafnium oxide, zirconium oxide, aluminum oxide, tantalum oxide, lanthanum oxide, or any combination thereof.

As shown in FIG. 2C, the seal ring 206 extends along the vertical direction (e.g., the Z direction). The seal ring 206 can extend from a side 220 (referred to as a bottom side) of the semiconductor device 200a to a side 222 (referred to as a top side) of the semiconductor device 200a along the vertical direction. The bottom side 220 and the top side 222 are opposite to each other along the vertical direction. The conductive layers 214A and the insulating layers 214B in the stack 214 are located along the vertical direction within a range defined by a length of the seal ring 206 along the vertical direction. In other words, the seal ring 206 extends beyond the stack 214 in both the top side 222 and the bottom side 220 along the vertical direction.

The seal ring 206 can have a top portion 224 and a bottom portion 226. In some implementations, the top portion 224 can include two dielectric portions 228 and a conductive portion 230 between the dielectric portions 228. The conductive portion 230 can be in contact with the dielectric portions 228. In some implementations, at least one of the dielectric portions 228 has a non-flat surface similar to, or same as, the surface 207a or the surface 207b as shown in FIG. 2A. The conductive portion 230 can include any suitable conducting material, such as W, Co, Cu, Al, TiN, polysilicon, doped silicon, silicides, or any combination thereof. Each of the dielectric portions 228 can include a dielectric material, such as silicon oxide, silicon nitride, silicon oxynitride, or any combination thereof. In some implementations, the conductive portion 230 can be a solid metal structure. The bottom portion 226 also is conductive and is connected to the conductive portion 230. In some implementations, the bottom portion 226 and the conductive portion 230 can be made of the same conductive material (e.g., metal). The bottom portion 226 can be exposed from the bottom side 220. The bottom portion 226 can be connected to an external component. In some implementations, the bottom portion 226 may not be considered as a part of the seal ring 206. For example, the bottom portion 226 may be considered as a separate conductive contact structure that is configured to couple the seal ring 206 to the external component.

In some implementations, the semiconductor device 200a further includes a semiconductor layer 232 adjacent to the bottom side 220. The semiconductor layer 232 can be made of any suitable semiconductor materials (e.g., polysilicon). The semiconductor layer 232 can be connected to the gate line structure 212 and the channel structures 208. For example, the semiconductor layer 232 can be connected to ends of the gate line structure 212 and the channel structures 208 that are closer to the bottom side 220. In some implementations, the semiconductor layer 232 can function as an array common source of memory strings (e.g., channel structures 208) of the semiconductor device 200a. The semiconductor layer 232 can be isolated from the bottom portion 226 (e.g., along the Y direction) by an isolating structure 234. The isolating structure 234 can include a dielectric material. The isolating structure 234 is between the semiconductor layer 232 and a bottom surface of the semiconductor device 200a along the Z direction. The isolating structure 234 can cover the semiconductor layer 232 and prevent the semiconductor layer 232 from being exposed from the semiconductor device 200a. Along the Z direction and with respect to the bottom side 220, a bottom surface of the semiconductor layer 232 can be higher than a bottom surface of the bottom portion 226. The bottom surface of the bottom portion 226 can be co-planar with a surface of the bottom side 220.

FIG. 2D illustrates an enlarged view of a region 236 of FIG. 2C. The seal ring 206 can have multiple portions sequentially connected along the vertical direction. Each of the multiple portions is in a respective deck of the multiple decks (e.g., 218a, 218b, and 218c) of the stack 214. For example, as shown in FIG. 2D, the seal ring 206 has a portion 238a in the deck 218a, a portion 238b in the deck 218b, and a portion 238c in the deck 218c. Each of the portions 238a, 238b, and 238c of the seal ring 206 can have a thickness (e.g., a size along the Y direction) gradually reducing along the vertical direction (e.g., the Z direction). For example, the portion 238b has a cross section 240 and a cross section 242 both perpendicular to the vertical direction. The cross section 240 is closer to the top side 222 than the cross section 242 along the vertical direction. A size of the cross section 240 along the Y direction is larger than a size of the cross section 242 along the Y direction. The portion 238b has a top end 244 and a bottom end 246 (e.g., along the Z direction). The top end 244 is closer to the top side 222 than the bottom end 246 along the vertical direction. The portion 238a has a top end (not shown) and a bottom end 248 (e.g., along the Z direction). The portion 238c has a top end 250 and a bottom end (not shown) (e.g., along the Z direction). The top end 244 of the portion 238b is connected to the bottom end 248 of the portion 238a. A size of a cross section of the top end 244 along the Y direction is larger than a size of a cross section of the bottom end 248. The bottom end 246 of the portion 238b is connected to the top end 250 of the portion 238c. A size of a cross section of the bottom end 246 along the Y direction is smaller than a size of a cross section of the top end 250. As shown in FIG. 2D, the gate line structure 212 and the channel structures 208 can also have multiple portions, which have structures similar to the portions 238a, 238b, and 238c of the seal ring 206, as described above.

FIGS. 3A-1 to 3P illustrate an example process of fabricating a semiconductor device, such as the semiconductor device 200a or 200b as illustrated in FIGS. 2A-2D. FIGS. 3A-1 to 3P show top views and cross-sectional views of example semiconductor structures at various stages of the fabrication process.

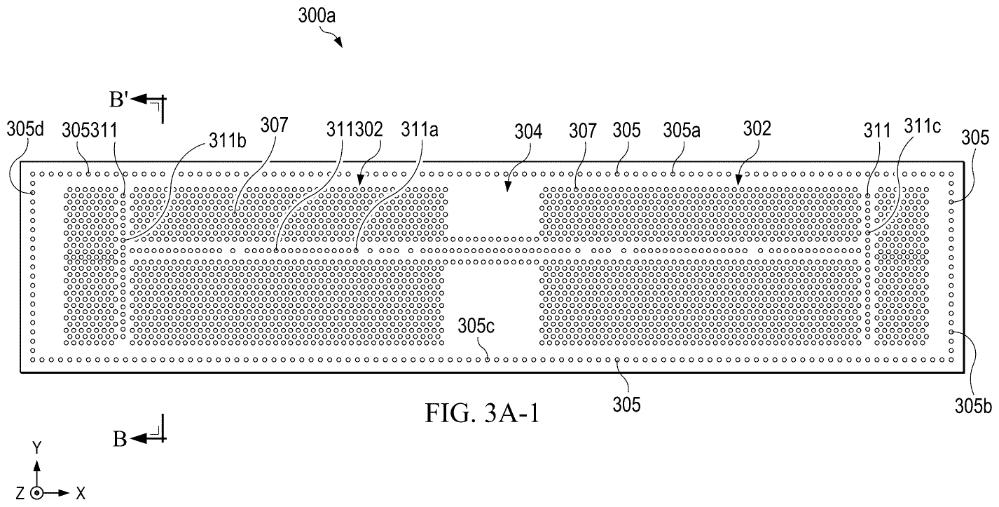

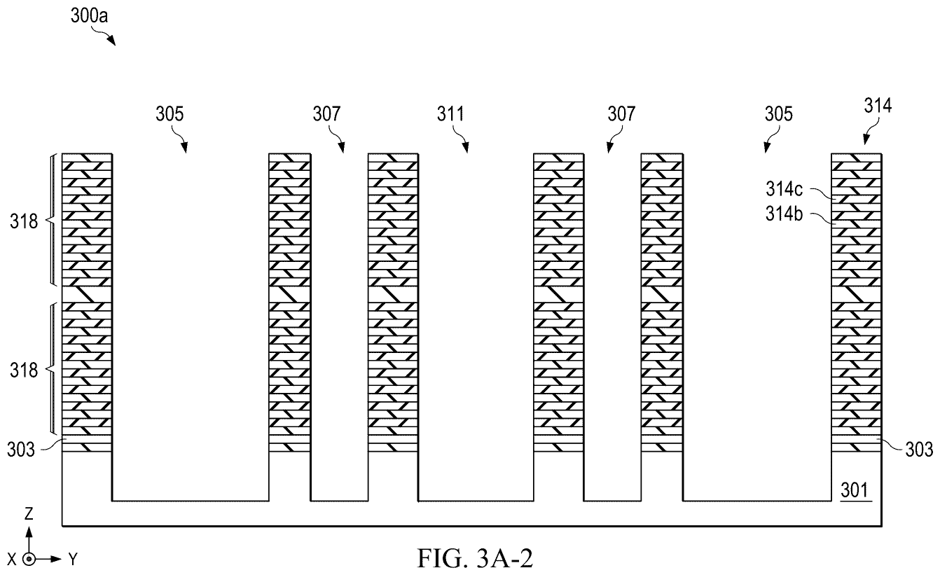

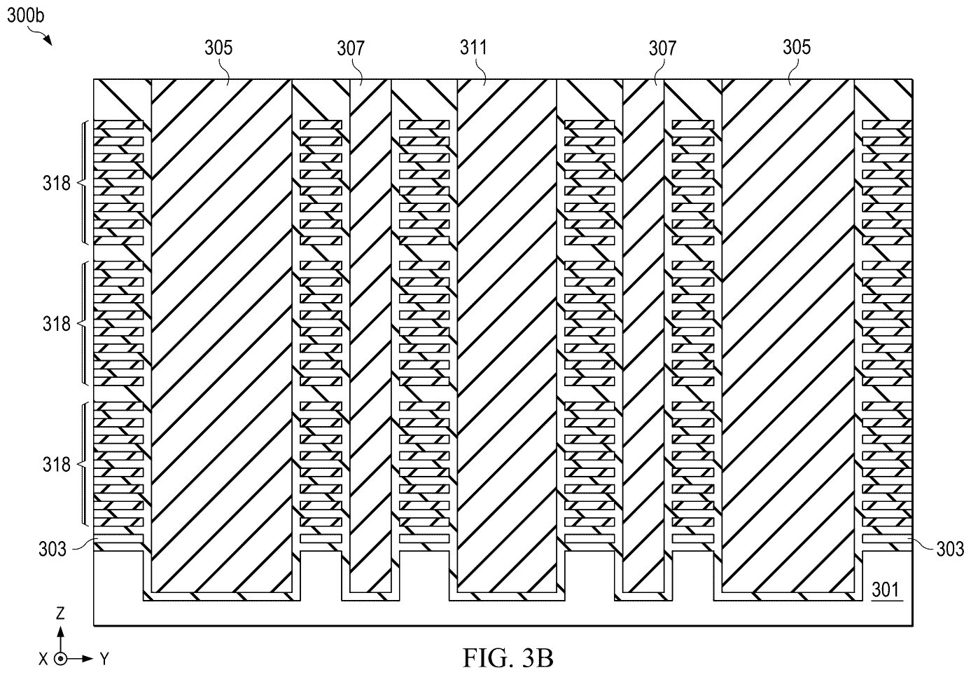

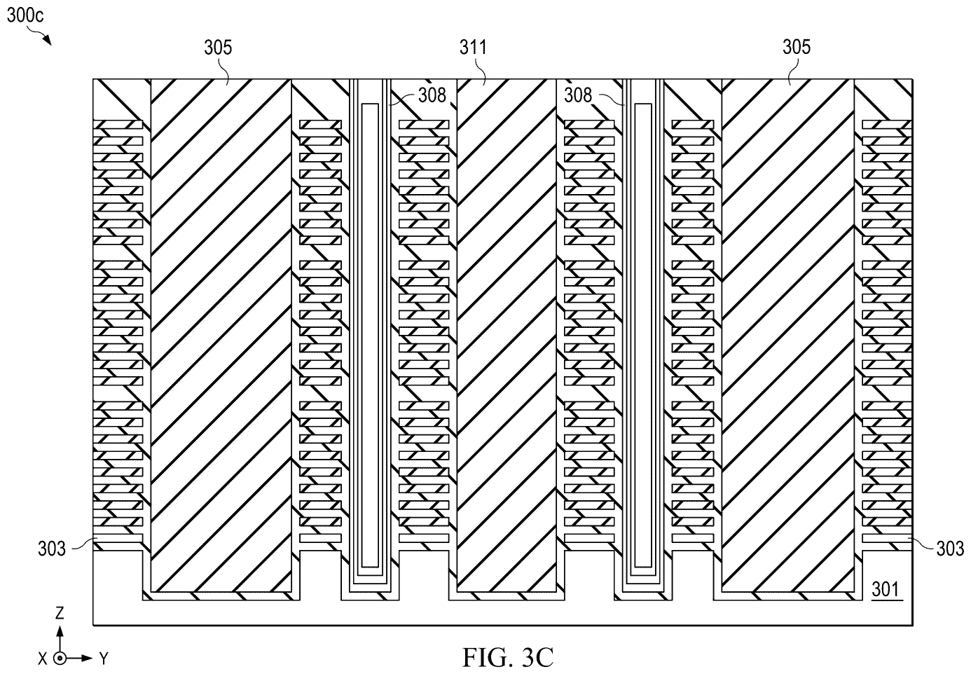

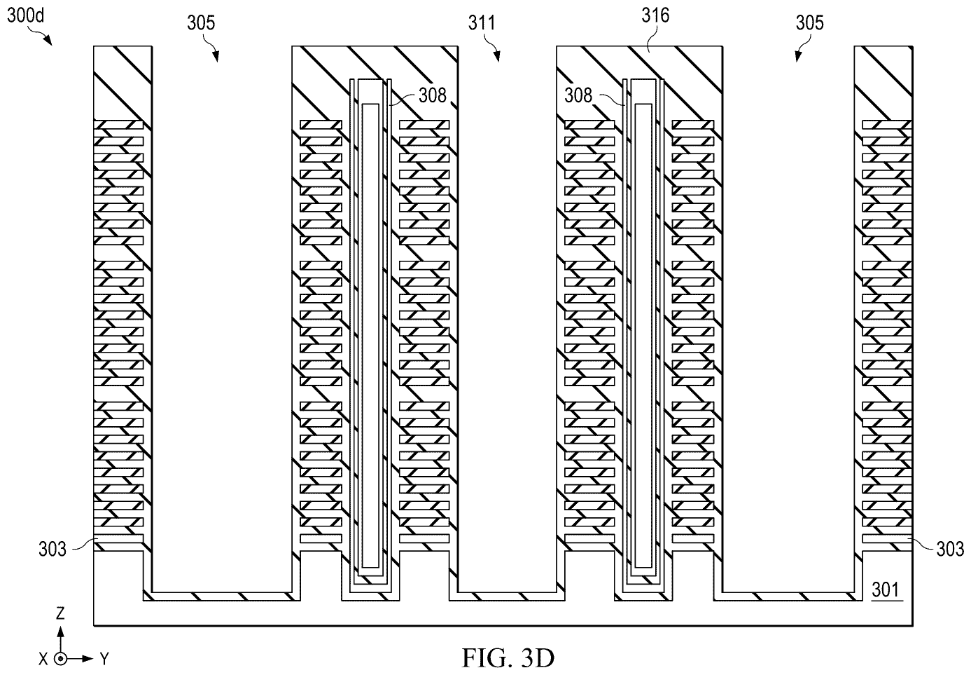

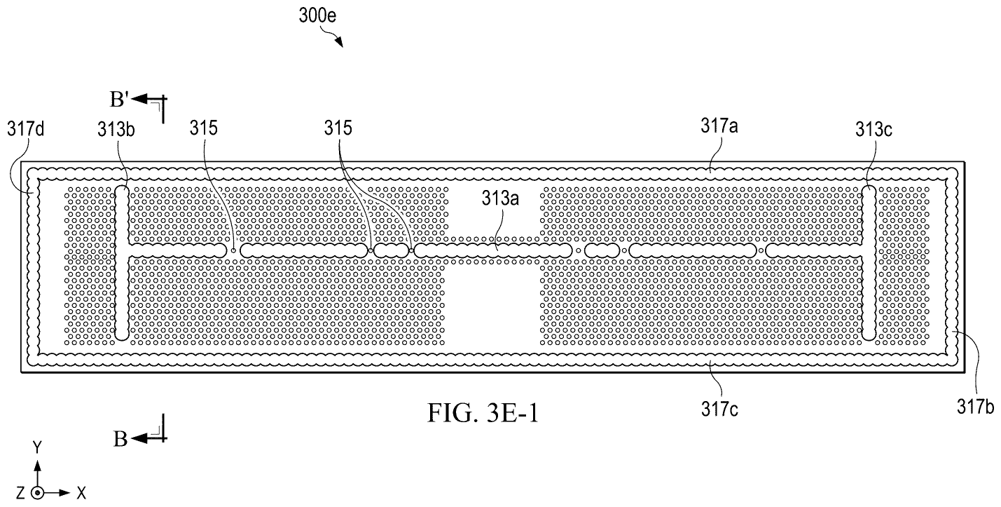

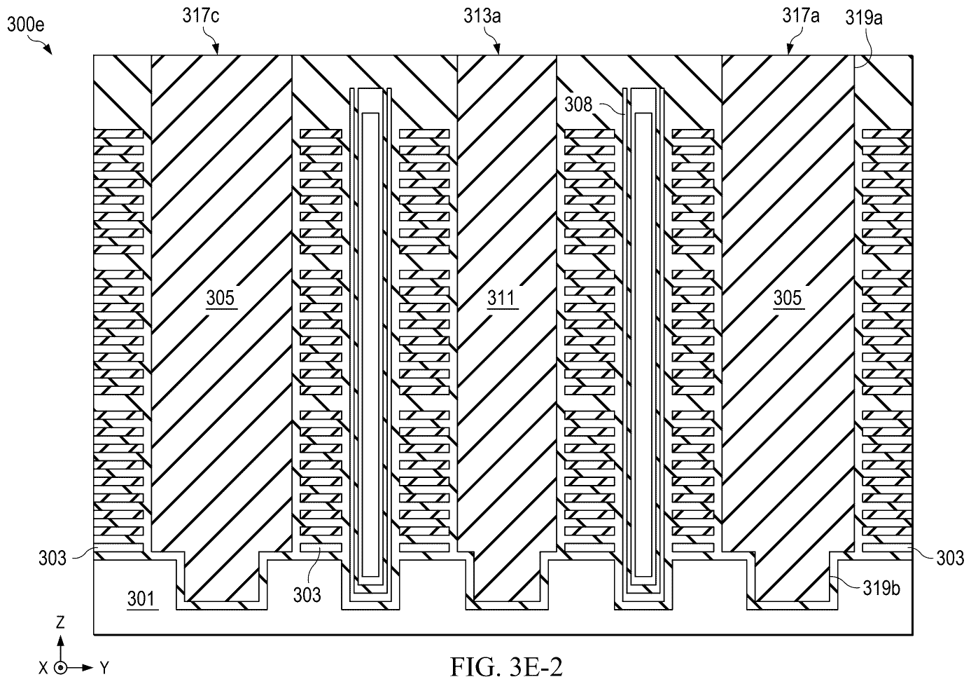

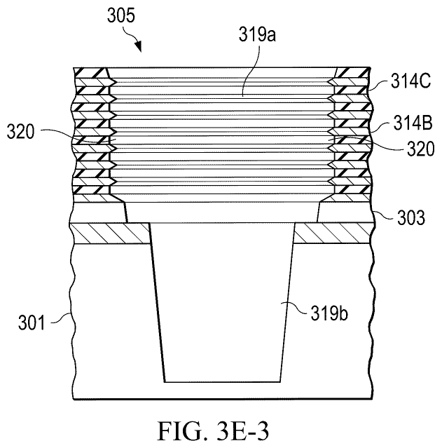

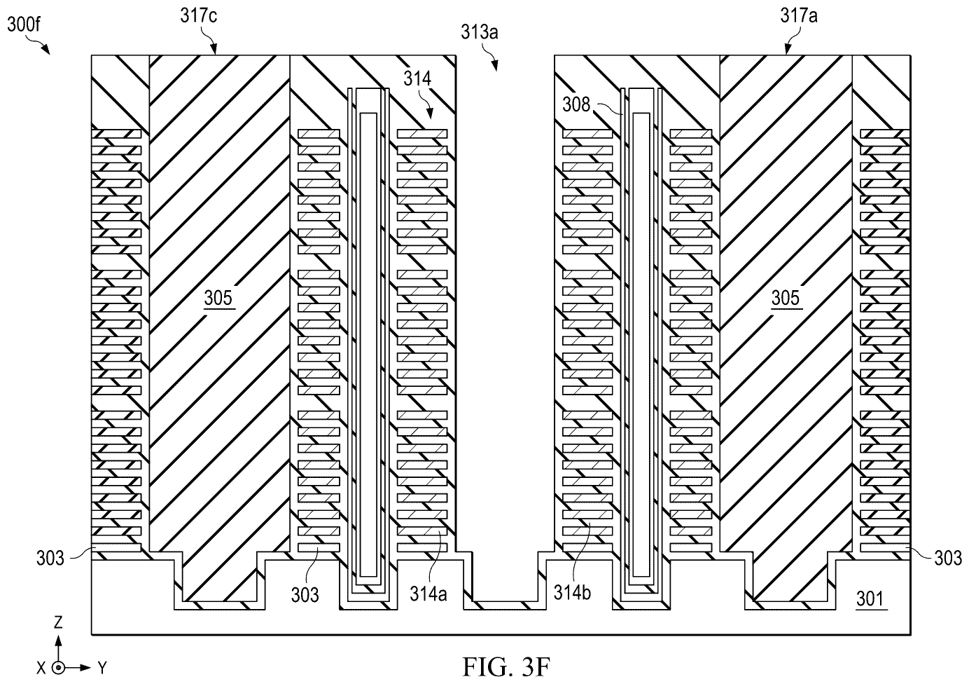

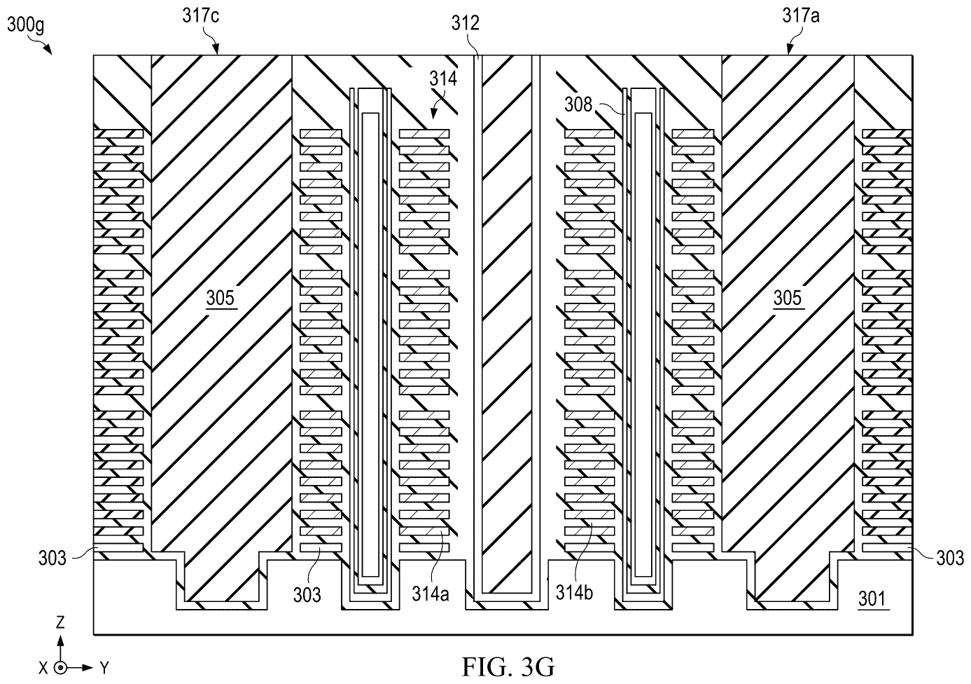

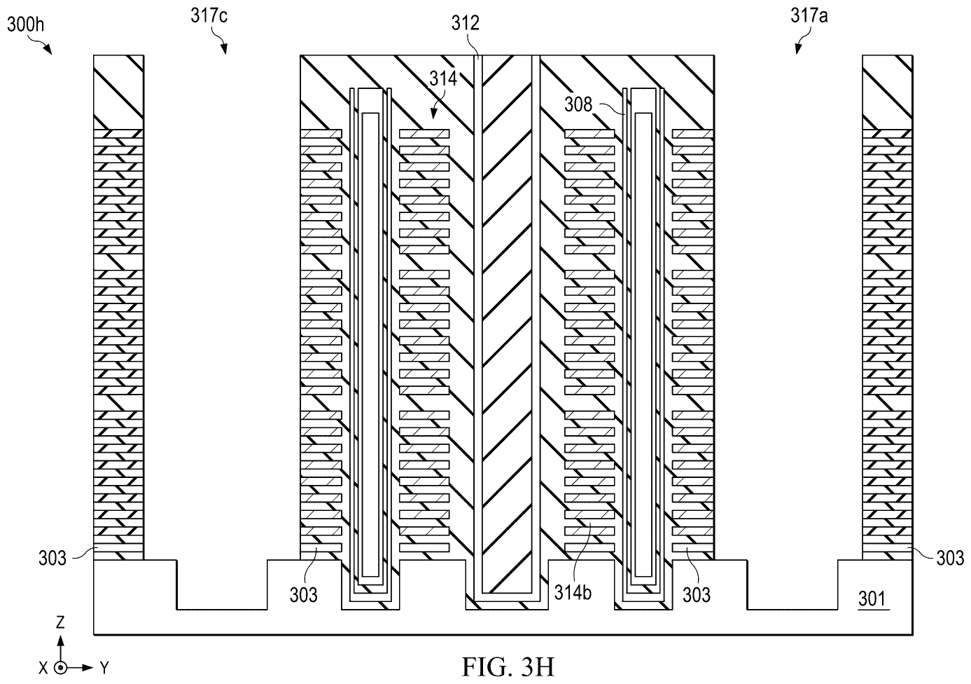

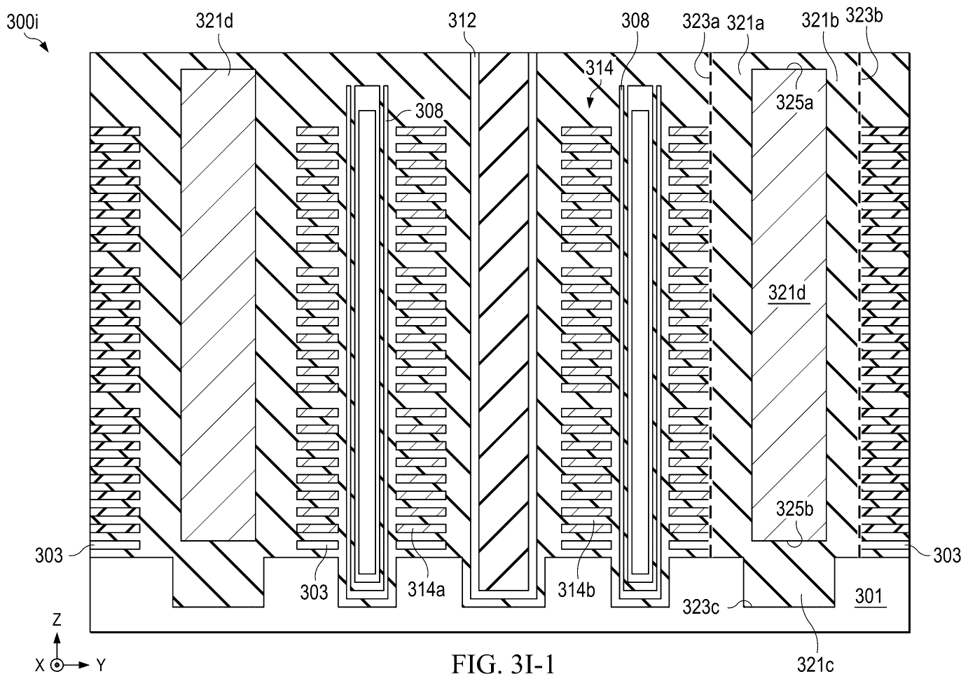

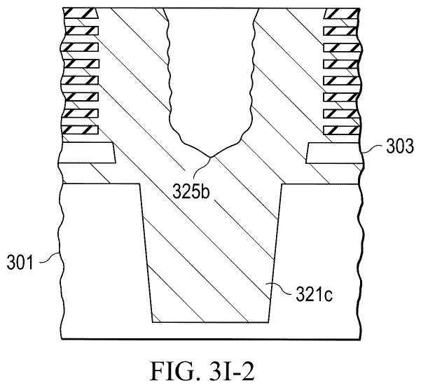

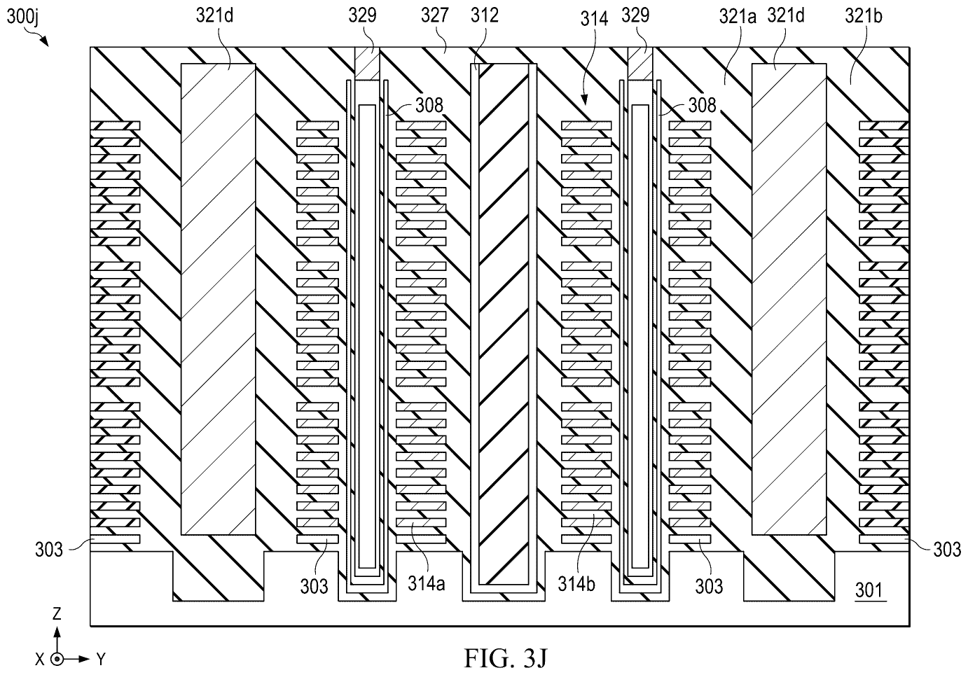

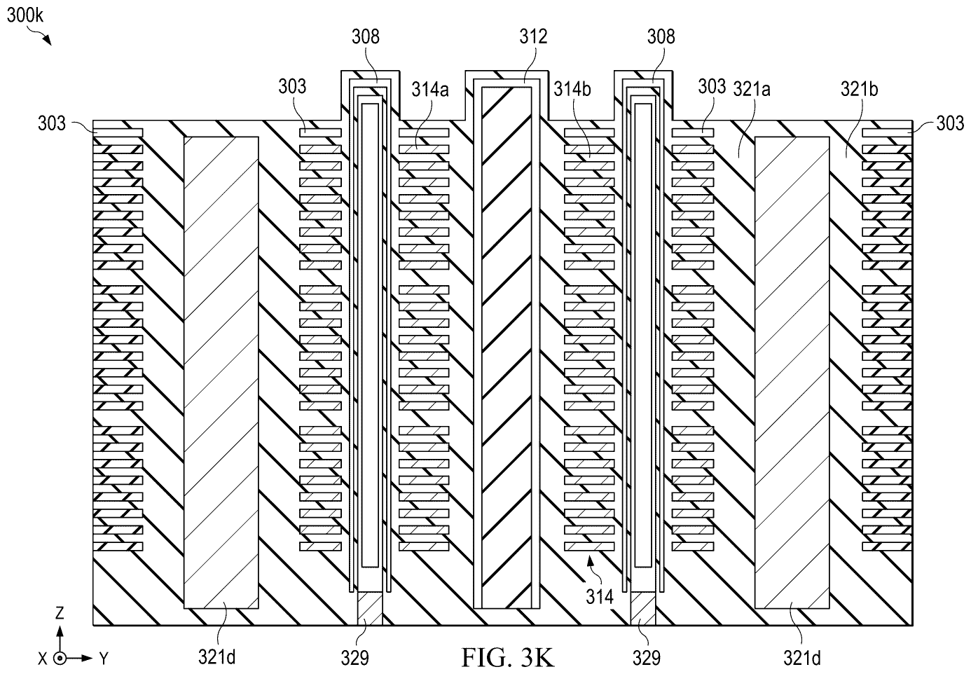

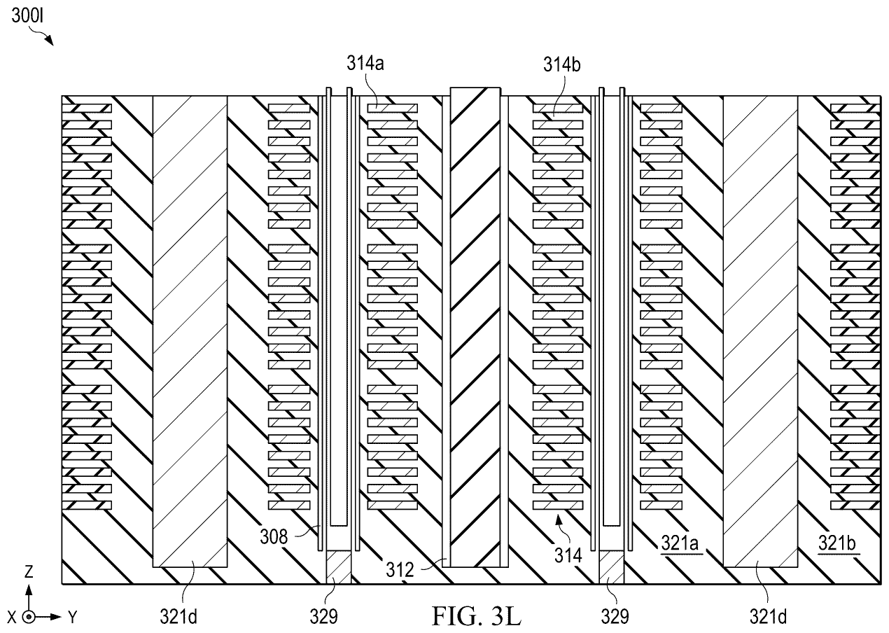

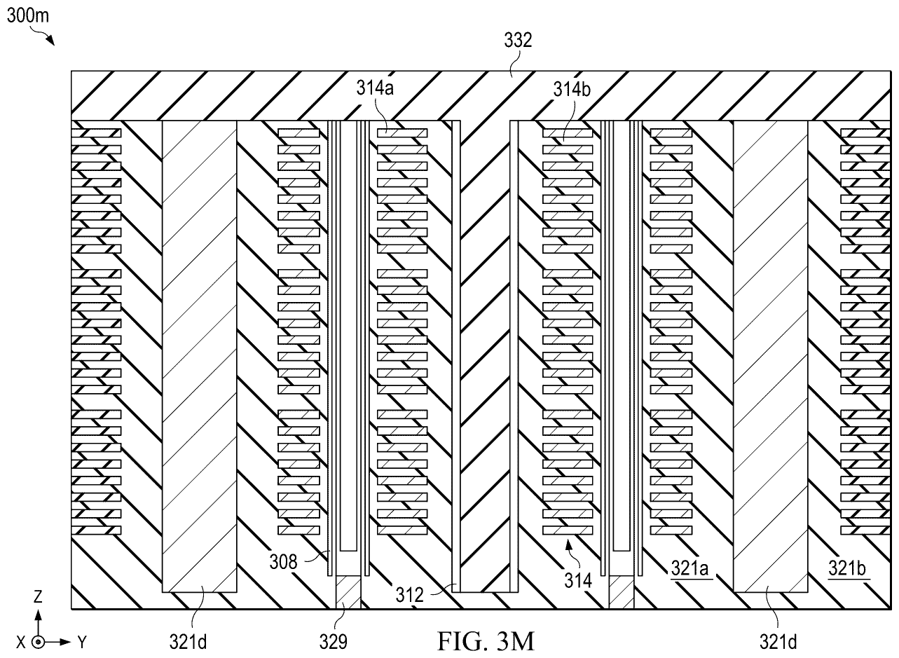

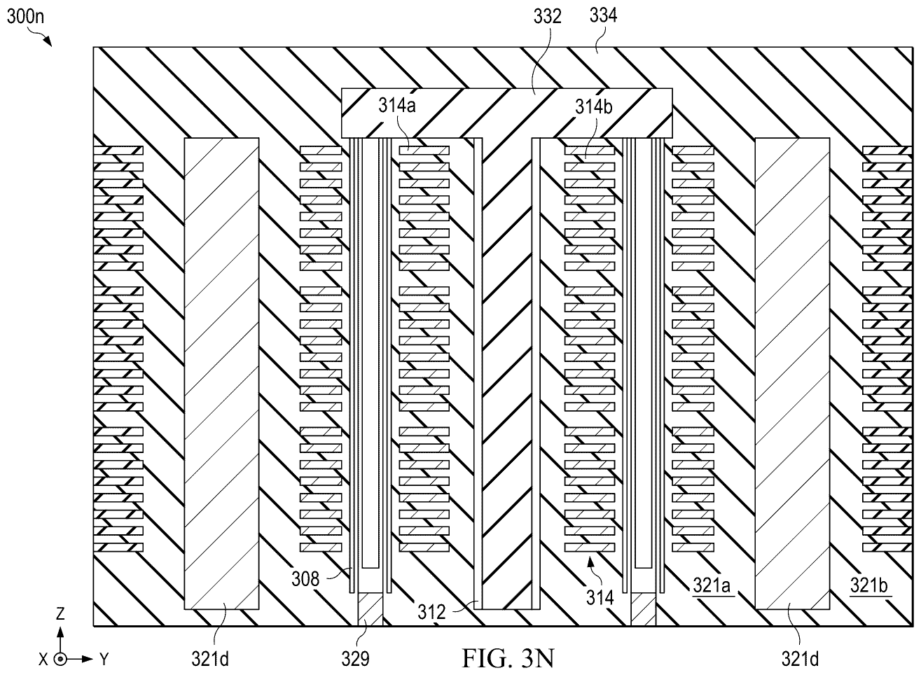

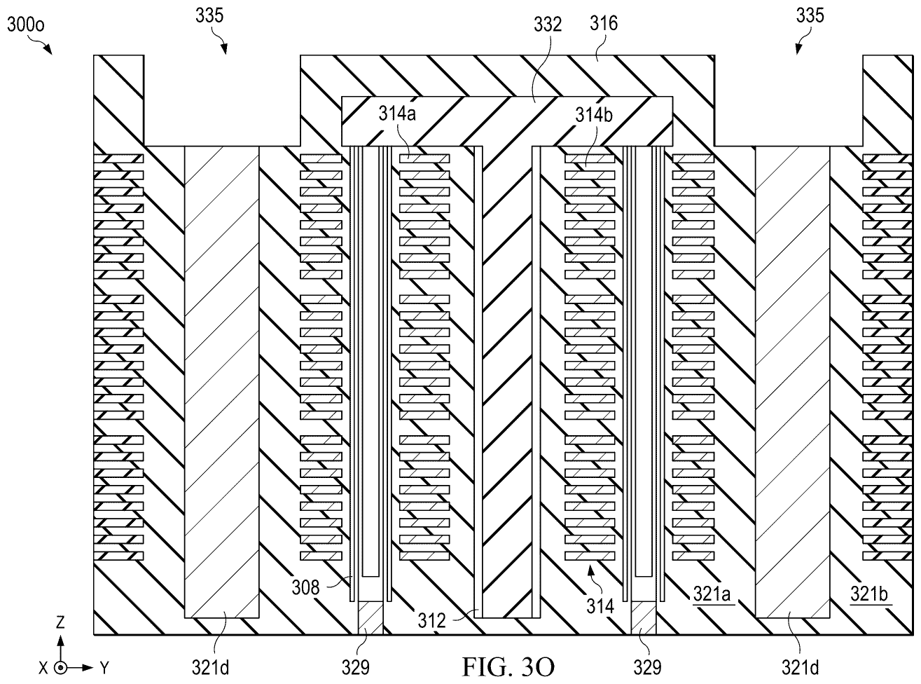

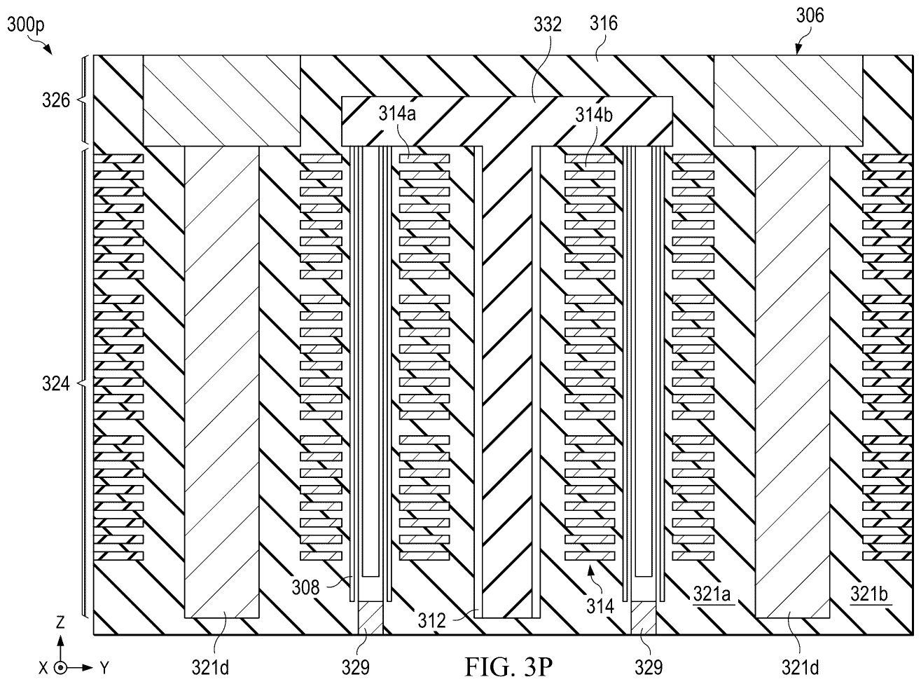

FIG. 3A-1 illustrates a top view of a semiconductor structure 300a. As shown in FIG. 3A-1, the semiconductor structure 300a includes two array regions 302 (that are similar to, or same as the array regions 202 of FIG. 2A) and a connection region 304 (that is similar to, or same as the connection region 204 of FIG. 2A). The semiconductor structure 300a can include seal ring holes 305, channel holes 307, and gate line holes 311. As shown in FIG. 3A-1, the channel holes 307 are in the array regions 302. The gate line holes 311 can be in the array regions 302 and the connection region 304. In some implementations, the gate line holes 311 include a group of gate line holes (e.g., gate line holes 311a) that are arranged and spaced along a line extending in the X direction. In some implementations, the gate line holes 311 further include other groups of gate line holes (e.g., gate line holes 311b and gate line holes 311c). Each group of the other groups of gate line holes are arranged and spaced along a line extending in the Y direction. The seal ring holes 305 can surround the array regions 302 and the connection region 304 in the X-Y plane. The seal ring holes 305 can include multiple groups of seal ring holes. Each group of the multiple groups of seal ring holes can be arranged along the X direction or the Y direction. For example, as shown in FIG. 3A-1, the seal ring holes 305 can include seal ring holes 305a arranged in a line extending along the X direction, seal ring holes 305b arranged in a line extending along the Y direction, seal ring holes 305c arranged in another line extending along the X direction, and seal ring holes 305d arranged in another line extending along the Y direction. In some implementations, these lines can form a rectangular shape surrounding the array regions 302 and the connection region 304.

FIG. 3A-2 illustrates a cross-sectional view (along cut line BB′ of FIG. 3A-1) of the semiconductor structure 300a. As shown in FIG. 3A-2, the semiconductor structure 300a includes a substrate 301 and a stack 314 of alternating sacrificial layers 314C and insulating layers 314B provided over the substrate 301. The sacrificial layers 314C and the insulating layers 314B can alternate in the vertical direction (e.g., the Z direction). The insulating layers 314B can include dielectric material, such as silicon oxide, silicon nitride, silicon oxynitride, or any combination thereof. In some implementations, the sacrificial layers 314C can include a dielectric material different from the dielectric material of the insulating layers 314B. For example, the insulating layers 314B can include silicon oxide, and the sacrificial layers 314C can include silicon nitride. The semiconductor structure 300a can further include a polysilicon layer 303 between the stack 314 and the substrate 301 along the vertical direction. The seal ring holes 305, the channel holes 307, and the gate line holes 311 can extend through the stack 314 and the polysilicon layer 303 and into the substrate 301 along the Z direction. The stack 314 can include multiple decks 318. In some implementations, the seal ring holes 305, the channel holes 307, and the gate line holes 311 in each deck 318 can be formed by a same etching process. For example, the seal ring holes 305, the channel holes 307, and the gate line holes 311 can be formed by an etching process using one etching mask (not shown) applied on top of the semiconductor structure 300a. The etching mask can have patterns designed for these holes.

As shown in FIG. 3B, a semiconductor structure 300b is formed by filling a filler material (e.g., polysilicon) into the seal ring holes 305, the channel holes 307, and the gate line holes 311.

As shown in FIG. 3C, a semiconductor structure 300c is formed by removing the filler material from the channel holes 307 and forming channel structures 308 in the channel holes 307. In some implementations, each of the channel structures 308 can be in the shape of a cylinder or a pillar, and can include a high-k layer, a block layer surrounded by the high-k layer, a charge trapping layer (or a storage layer) surrounded by the block layer, a tunneling layer surrounded by the charge trapping layer, a channel layer surrounded by the tunneling layer, and a core filler layer surrounded by the channel layer, and a channel plug formed above the core filler layer and being in contact with the channel layer. In some implementations, the channel layer can include silicon, such as amorphous silicon, polysilicon, or single crystalline silicon, the tunneling layer can include silicon oxide, silicon nitride, or any combination thereof, the blocking layer can include silicon oxide, silicon nitride, high-k dielectrics, or any combination thereof, and the charge trapping layer can include silicon nitride, silicon oxynitride, silicon, or any combination thereof. In some implementations, the tunneling layer, the charge trapping layer and the blocking layer, collectively referred to as a memory film, can include ONO dielectrics (silicon Oxide-silicon Nitride-silicon Oxide). In some implementations, each channel structure 308 can be formed by forming the high-k layer, the block layer, the charge trapping layer, the tunneling layer, the channel layer, the core filler layer, and the channel plug in a respective channel hole 307.

As shown in FIG. 3D, a semiconductor structure 300d is formed by depositing a dielectric layer 316 on top of the semiconductor structure 300c to cover the channel structures 308. Openings are formed in the dielectric layer 316 to expose the filler material in the seal ring holes 305 and the gate line holes 311. Then, the filler material in the seal ring holes 305 and the gate line holes 311 is removed.

FIG. 3E-1 illustrates a top view of a semiconductor structure 300c. FIG. 3E-2 illustrates a cross-sectional view of the semiconductor structure 300e along the cut line BB'. The semiconductor structure 300e can be formed by expanding the seal ring holes 305 and the gate line holes 311 and filling a filler material into the expanded seal ring holes 305 and the expanded gate line holes 311. In some implementations, the seal ring holes 305 and the gate line holes 311 can be expanded by a same etching process. For example, an etchant can be filled into the seal ring holes 305 and the gate line holes 311 to etch off a part of the stack 314 exposed by the seal ring holes 305 and the gate line holes 311. In some implementations, the expanded gate line holes within each group of gate line holes (e.g., gate line holes 311a, gate line holes 311b, or gate line holes 311c as shown in FIG. 3A-1) are connected with each other along the X direction or the Y direction and form gate line trenches. For example, the gate line holes 311a are expanded and form a gate line trench 313a extending along the X direction, the gate line holes 311b are expanded and form a gate line trench 313b extending along the Y direction, and the gate line holes 311c are expanded and form a gate line trench 313c extending along the Y direction. The gate line trench 313a can be connected to the gate line trenches 313b and 313c to form a T shape or an H shape. In some implementations, a gate line trench (e.g., the gate line trench 313a as shown in FIG. 3E-1) can be separated by isolating structures 315. In some implementations, the expanded seal ring holes within each group of seal ring holes (e.g., seal ring holes 305a, seal ring holes 305b, seal ring holes 305c, or seal ring holes 305d as shown in FIG. 3A-1) are connected with each other along the X direction or the Y direction and form seal ring trenches. For example, the seal ring holes 305a are expanded and form a seal ring trench 317a extending along the X direction, the seal ring holes 305b are expanded and form a seal ring trench 317b extending along the Y direction, the seal ring holes 305c are expanded and form a seal ring trench 317c extending along the X direction, and the seal ring holes 305d are expanded and form a seal ring trench 317d extending along the Y direction. The seal ring trenches 317a-317d can be connected to form a rectangular shape and enclose the gate line trenches 313a-313c in the X-Y plane.

As shown in FIG. 3E-2, the expanded seal ring hole 305 can include a body portion 319a above the substrate 301 and a bottom portion 319b in the substrate 301. The bottom portion 319b can be narrower than the body portion 319a along the Y direction since during the etching process the substrate 301 may not be etched off by the etchant or may be etched off slower than the stack 314. For example, a size of a cross section of the bottom portion 319b along the Y direction is smaller than a size of a cross section of the body portion 319a along the Y direction.

FIG. 3E-3 illustrates an enlarged view of the bottom portion 319b and a part of the body portion 319a of the expanded seal ring hole 305. The etching process can cause recesses of difference sizes to the insulating layers 314B and the sacrificial layers 314C, depending on materials of the insulating layers 314B and the sacrificial layers 314C and a type of the etchant. For example, as shown in FIG. 3E-3, each of the sacrificial layers 314C has a larger recess than the insulating layer 314B after the etching process. Thus, in some implementations, a cross section (e.g., in the Y-Z plane) of the body portion 319a can have two wave-like boundaries 320.

As shown in FIG. 3F, a semiconductor structure 300f is formed. The filler material can be removed from the gate line trenches 313a-313c of the semiconductor structure 300f. The semiconductor structure 300f includes conductive layers 314A formed by replacing the sacrificial layers 314C of the stack 314 with a conductive material (e.g., W). For example, the conductive layers 314A can be formed by removing the sacrificial layers 314C by an etching process and depositing at least one conductive material into the gate line trenches 313a-313c. In some implementations (as shown in FIG. 3F), the sacrificial layers 314C within a region surrounded by the seal ring trenches 317a-317d are replaced with the conductive layers 314A, and the sacrificial layers 314C outside of the region surrounded by the seal ring trenches 317a-317d are not changed. In some other implementations (not shown), the sacrificial layers 314C outside of the region surrounded the seal ring trenches 317a-317d also can be replaced with the conductive layers 314A.

As shown in FIG. 3G, a semiconductor structure 300g is formed. The semiconductor structure 300g includes a gate line structure 312, which can be formed by depositing at least a semiconductor material (e.g., polysilicon) into the gate line trenches 313a-313c.

As shown in FIG. 3H, a semiconductor structure 300h is formed by removing the filler material from the seal ring trenches 317a-317d.

FIGS. 3I-1 to 3I-2 illustrate a semiconductor structure 300i. As shown in FIG. 3I-1, in each of the seal ring trenches 317a-317d, the semiconductor structure 300i can include a dielectric portion 321a, a dielectric portion 321b, and a dielectric bottom layer 321c, and a conductive portion 321d. The dielectric portion 321a, the dielectric portion 321b, and the conductive portion 321d can extend along the vertical direction (e.g., the Z direction). The dielectric portion 321a, the dielectric portion 321b, and the dielectric bottom layer 321c can be formed by depositing a dielectric material (e.g., silicon oxide) into the seal ring trenches 317a-317d. The dielectric portion 321a is in contact with a sidewall (also referred to as an inner surface) 323a of the seal ring trenches 317a-317d. The dielectric portion 321b is in contact with a sidewall (also referred to as an inner surface) 323b of the seal ring trenches 317a-317d. The dielectric bottom layer 321c is in contact with a bottom 323c of the seal ring trenches 317a-317d. The dielectric portions 321a and 321b are connected by the dielectric bottom layer 321c.

The conductive portion 321d can be formed by filling a conductive material (e.g., W) between the dielectric portion 321a and the dielectric portion 321b (e.g., along the Y direction). In some implementations, the conductive portion 321d can be a solid metal structure. The conductive portion 321d can have a top end 325a and a bottom end 325b (e.g., along the Z direction). The bottom end 325b is closer to the substrate 301 along the Z direction than the top end 325a. In some implementations, the bottom end 325b (also referred to as the bottom of the conductive portion 321d) is above the polysilicon layer 303 along the Z direction. In some other implementations, as shown in another example illustrated by FIG. 3I-2, the bottom end 325b and the polysilicon layer 303 are located at approximately the same position along the Z direction. The bottom end 325b can have any suitable profile or shape (e.g., a flat bottom as shown in FIG. 3I-1 or a non-flat bottom with a pointy end as shown in FIG. 3I-2) depending on the shape of the dielectric bottom layer 321c.

In some implementations, forming the conductive portion 321d having a solid metal structure and with its bottom above the polysilicon layer 303 can avoid the structure of the conductive portion 321d being damaged (e.g., the W loss issue) in a later process (e.g., when the substrate 301 and the polysilicon layer 303 are removed as described with reference to FIGS. 3K and 3L). In some implementations, even if a small part of the bottom of the conductive portion 321d is removed or lost, the remaining part of the conductive portion 321d still remains intact and thus can provide protection to components surrounded by the conductive portion 321d.

As shown in FIG. 3J, a semiconductor structure 300j is formed by depositing a dielectric layer 327 on top of the semiconductor structure 300i. The dielectric layer 327 can cover the gate line structure 312 and the conductive portion 321d. Contact structures 329 can be formed in the dielectric layer 327. Each contact structure 329 can be configured to couple a respective channel structure 308 to an external component. In some implementations, one end of the contact structure 329 is connected to the channel plug of the channel structure 308, and another end of the contact structure 329 is exposed from the dielectric layer 327.

As shown in FIG. 3K, a semiconductor structure 300k is formed by flipping the semiconductor structure 300j upside down and removing the substrate 301.

As shown in FIG. 3L, a semiconductor structure 3001 is formed by removing the polysilicon layer 303. In addition, a part of each channel structure 308 that was in the substrate 301 can be removed. For example, as shown in FIG. 3L, a part of the channel structure 308′s memory film that includes the ONO dielectrics (silicon Oxide-silicon Nitride-silicon Oxide) can be removed. Thus, the core filler layer of the channel structure 308 can be exposed. A part of the gate line structure 312 that was in the substrate 301 also can be removed to expose the semiconductor material of the gate line structure 312.

As shown in FIG. 3M, a semiconductor structure 300m is formed by depositing a semiconductor layer 332 on top of the semiconductor structure 300l. The semiconductor layer 332 can include any suitable semiconductor materials (e.g., polysilicon). The semiconductor layer 332 is connected to the gate line structure 312 and the channel structures 308.

As shown in FIG. 3N, a semiconductor structure 300n is formed by removing a part of the semiconductor layer 332 that is on top of the dielectric portions 321a and 321b and the conductive portion 321d. The semiconductor structure 300n further includes an isolating structure 334. The isolating structure 334 can be formed by depositing a dielectric material (e.g., silicon oxide) on top of the dielectric portions 321a and 321b, the conductive portion 321d, and the remaining part of the semiconductor layer 332.

As shown in FIG. 3O, a semiconductor structure 3000 is formed by forming a trench 335 in the isolating structure 334. The trench 335 can surround the array regions 302 and the connection region 304 in the X-Y plane. The trench 335 can be on top of the conductive portion 321d and expose the conductive portion 321d.

FIG. 3P illustrates a semiconductor structure 300p that includes a conductive structure 326 in the trench 335. The conductive structure 326 can be formed by depositing a conductive material (e.g., W) into the trench 335. As shown in FIG. 3P, one side of the conductive structure 326 is connected to the conductive portion 321d, and another side of the conductive structure 326 is exposed form the semiconductor structure 300p. The semiconductor structure 300p includes a seal ring 306 (also referred to as a protection structure or a seal ring structure). The seal ring 306 includes the dielectric portion 321a, the dielectric portion 321b, the conductive portion 321d, and the conductive structure 326. In some implementations, the dielectric portion 321a, the dielectric portion 321b, and the conductive portion 321d can be considered as a top portion 324 of the seal ring 306, and the conductive structure 326 can be considered as a bottom portion of the seal ring 306. The seal ring 306 is similar to, or same as, the seal ring 206 of FIGS. 2A-2D. The seal ring 306 includes at least one surface (e.g., a surface of the top portion 324 that is in contact with sidewall 323a or sidewall 323b) that includes a series of curved portions connected together. The semiconductor structure 300p can be an example of the semiconductor device 200a or 200b illustrated by FIGS. 2A-2D.

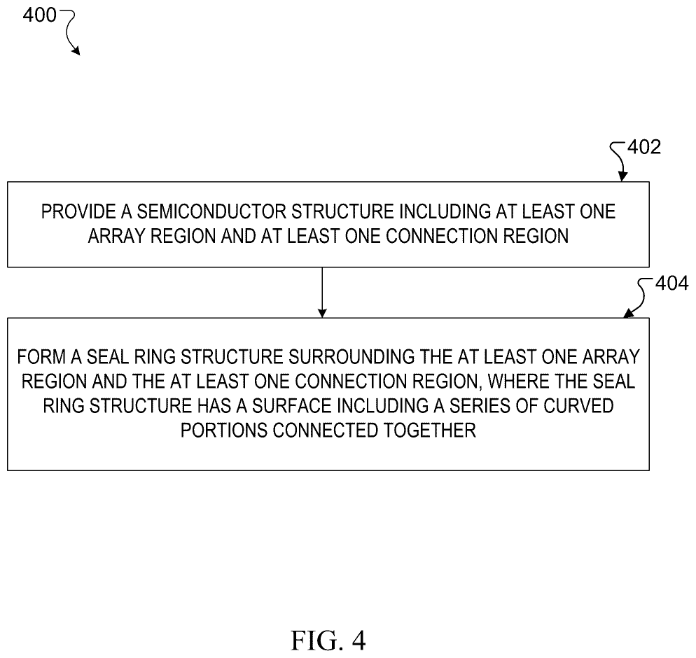

FIG. 4 illustrates a flow chart of an example process 400. The process 400 can be performed to form a semiconductor device. The semiconductor device can be similar to, or same as, the semiconductor device 200a or 200b illustrated by FIGS. 2A-2D. The process 400 can be described in view of FIGS. 3A-1 to 3P. The process 400 can include one or more steps of the fabrication process of forming the semiconductor structures in FIGS. 3A-1 to 3P. It is understood that the operations shown in process 400 are not exhaustive and that other operations can be performed as well before, after, or between any of the illustrated operations. Further, some of the operations may be performed simultaneously, or in a different order than shown in FIG. 4.

At operation 402, a semiconductor structure (e.g., the semiconductor structures 300a-300p of FIGS. 3A-1 to 3P) including at least one array region (e.g., the array regions 302) and at least one connection region (e.g., the connection region 304) is provided.

At operation 404, a seal ring structure (e.g., the seal ring 306 of FIG. 3P) surrounding the at least one array region and the at least one connection region (e.g., in the X-Y plane) is formed. The seal ring structure can have at least a surface (e.g., a surface of the top portion 324 of the seal ring 306 that is in contact with sidewall 323a or sidewall 323b) including a series of curved portions connected together.

In some implementations, providing the semiconductor structure includes providing the semiconductor structure including a substrate (e.g., the substrate 301 of FIG. 3P) and a stack (e.g., the stack 314 of FIG. 3A-2) of sacrificial layers (e.g., the sacrificial layers 314C) and insulating layers (e.g., the insulating layers 314B) alternating with each other along a first direction (e.g., the Z direction).

In some implementations, forming the seal ring structure includes forming gate line holes (e.g., the gate line holes 311 of FIG. 3A-2), channel holes (e.g., the channel holes 307 of FIG. 3A-2), and seal ring holes (e.g., the seal ring holes 305 of FIG. 3A-2) extending through the stack and into the substrate along the first direction. The seal ring holes surround the gate line holes and the channel holes.

In some implementations, forming the seal ring structure further includes forming seal ring trenches (e.g., the seal ring trenches 317a-317d of FIG. 3E-1) and one or more gate line trenches (e.g., the gate line trenches 313a-313c of FIG. 3E-1) by expanding the seal ring holes and the gate line holes. The seal ring trenches are connected and enclose the one or more gate line trenches.

In some implementations, forming the seal ring structure further includes forming the seal ring structure (e.g., the seal ring 306 of FIG. 3P) in the connected seal ring trenches. At least one surface of the seal ring structure is non-flat.

In some implementations, the stack includes one or more decks (e.g., the decks 318 of FIG. 3A-2). The gate line holes, the channel holes, and the seal ring holes in at least one of the one or more decks are formed by a same etching process (e.g., as described with reference to FIG. 3A-2).

In some implementations, the gate line holes include one or more groups of gate line holes (e.g., gate line holes 311a, gate line holes 311b, and gate line holes 311c of FIG. 3A-1). Each group of the one or more groups of gate line holes are arranged along a second direction (e.g., the X direction) perpendicular to the first direction or a third direction (e.g., the Y direction) perpendicular to the first direction and the second direction.

In some implementations, the seal ring holes include groups of seal ring holes (e.g., seal ring holes 305a, seal ring holes 305b, seal ring holes 305c, and seal ring holes 305d of FIG. 3A-1). Each group of the groups of seal ring holes are arranged along the second direction or the third direction.

In some implementations, one of the one or more gate line trenches includes expanded gate line holes formed from a corresponding group of the one or more groups of gate line holes, and the expanded gate line holes are connected with each other along a corresponding one of the second direction and the third direction (e.g., as described with reference to FIG. 3E-1).

In some implementations, one of the seal ring trenches includes expanded seal ring holes formed from a corresponding group of the groups of seal ring holes, and the expanded seal ring holes are connected with each other along a corresponding one of the second direction and the third direction (e.g., as described with reference to FIG. 3E-1).

In some implementations, one of the expanded seal ring holes includes a body portion (e.g., the body portion 319a of FIG. 3E-2) above the substrate and a bottom portion (e.g., the bottom portion 319b of FIG. 3E-2) in the substrate. In some implementations, a size of a cross section of the bottom portion (e.g., along the Y direction) is smaller than a size of a cross section of the body portion (e.g., along the Y direction).

In some implementations, the process 400 further includes forming channel structures (e.g., the channel structures 308 of FIG. 3C) in the channel holes.

In some implementations, the process 400 further includes forming conductive layers (e.g., the conductive layers 314A of FIG. 3F) between the insulating layers by depositing at least one conductive material into the one or more gate line trenches.

In some implementations, the process 400 further includes forming one or more gate line structures (e.g., the gate line structure 312 of FIG. 3G) in the one or more gate line trenches.

In some implementations, forming the seal ring structure in the connected seal ring trenches includes forming a first dielectric portion (e.g., the dielectric portion 321a of FIG. 3I-1), a second dielectric portion (e.g., the dielectric portion 321b of FIG. 3I-1), and a dielectric bottom layer (e.g., the dielectric bottom layer 321c of FIG. 3I-1) in the connected seal ring trenches by depositing a dielectric material into the connected seal ring trenches. The first dielectric portion is in contact with a first sidewall (e.g., the sidewall 323a of FIG. 3I-1) of the connected seal ring trenches. The second dielectric portion is in contact with a second sidewall (e.g., the sidewall 323b of FIG. 3I-1) of the connected seal ring trenches. The dielectric bottom layer is in contact with a bottom (e.g., the bottom 323c of FIG. 3I-1) of the connected seal ring trenches. The first dielectric portion is connected to the second dielectric portion by the dielectric bottom layer.

In some implementations, forming the seal ring structure in the connected seal ring trenches further includes forming a conductive portion (e.g., the conductive portion 321d of FIG. 3I-1) by filling a conductive material between the first dielectric portion and the second dielectric portion.

In some implementations, the semiconductor structure further includes a polysilicon layer (e.g., the polysilicon layer 303 of FIG. 3I-1) between the stack (e.g., the stack 314) and the substrate (e.g., the substrate 301). A bottom (e.g., the bottom end 325b of FIG. 3I-1) of the conductive portion can be above the polysilicon layer along the first direction.

In some implementations, the process 400 further includes removing the substrate and the dielectric bottom layer (e.g., as described with reference to FIG. 3K).

In some implementations, the process 400 further includes forming a conductive structure (e.g., the conductive structure 326 of FIG. 3P) connected to the conductive portion. The conductive structure can be exposed from a surface of the semiconductor structure.

In some implementations, the process 400 further includes forming a semiconductor layer (e.g., the semiconductor layer 332 of FIG. 3N) connected to the one or more gate line structures and the channel structures. The semiconductor layer can include a polysilicon material.

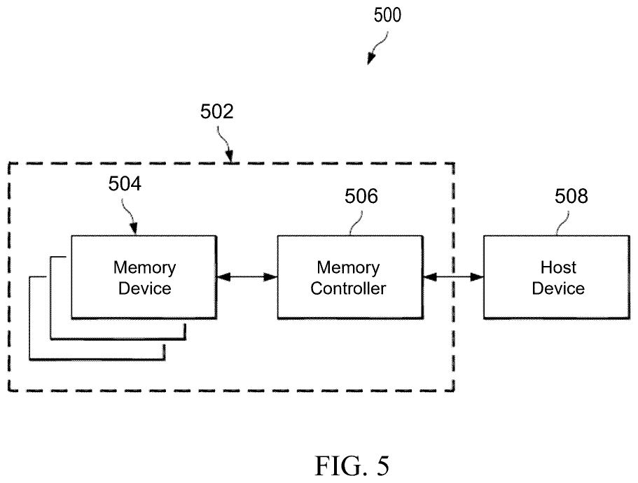

FIG. 5 illustrates a block diagram of an example system 500. The system 500 can have one or more semiconductor devices (e.g., memory devices), according to one or more implementations of the present disclosure. The system 500 can be a mobile phone, a desktop computer, a laptop computer, a tablet, a vehicle computer, a gaming console, a printer, a positioning device, a wearable electronic device, a smart sensor, a virtual reality (VR) device, an argument reality (AR) device, or any other suitable electronic devices having storage therein. As shown in FIG. 5, the system 500 can include a host device 508 and a memory system 502 having one or more memory devices 504 and a memory controller 506. Host device 508 can include a processor of an electronic device, such as a central processing unit (CPU), or a system-on-chip (SoC), such as an application processor (AP). Host device 508 can be configured to send or receive data to or from the one or more memory devices 504.

A memory device 504 can be any memory device disclosed herein, such as a memory device (e.g., a NAND Flash memory) as shown in FIGS. 2A-2D. Memory controller 506 (a.k.a., a controller circuit) is coupled to memory device 504 and host device 508. Consistent with implementations of the present disclosure, memory device 504 can include a plurality of conductive interconnections through a cover layer that are in contact with conductive pads in a conductive pad layer, and memory controller 506 can be coupled to memory device 504 through at least one of the plurality of conductive interconnections. Memory controller 506 is configured to control memory device 504. For example, memory controller 506 may be configured to operate a plurality of channel structures via word lines. Memory controller 506 can manage data stored in memory device 504 and communicate with host device 508.

In some implementations, memory controller 506 is designed/configured for operating in a low duty-cycle environment like secure digital (SD) cards, compact Flash (CF) cards, universal serial bus (USB) Flash drives, or other media for use in electronic devices, such as personal computers, digital cameras, mobile phones, etc. In some implementations, memory controller 406 is designed/configured for operating in a high duty cycle environment SSDs or embedded multi-media-cards (eMMCs) used as data storage for mobile devices, such as smartphones, tablets, laptop computers, etc., and enterprise storage arrays. Memory controller 506 can be configured to control operations of memory device 504, such as read, erase, and program (or write) operations. Memory controller 506 can also be configured to manage various functions with respect to the data stored or to be stored in memory device 504 including, but not limited to bad-block management, garbage collection, logical-to-physical address conversion, wear leveling, etc. In some implementations, memory controller 506 is further configured to process error correction codes (ECCs) with respect to the data read from or written to memory device 504. Any other suitable functions may be performed by memory controller 506 as well, for example, formatting memory device 504.

Memory controller 506 can communicate with an external device (e.g., host device 508) according to a particular communication protocol. For example, memory controller 506 may communicate with the external device through at least one of various interface protocols, such as a USB protocol, an MMC protocol, a peripheral component interconnection (PCI) protocol, a PCIexpress (PCI-E) protocol, an advanced technology attachment (ATA) protocol, a serial-ATA protocol, a parallel-ATA protocol, a small computer small interface (SCSI) protocol, an enhanced small disk interface (ESDI) protocol, an integrated drive electronics (IDE) protocol, a Firewire protocol, etc.

Memory controller 506 and one or more memory devices 504 can be integrated into various types of storage devices, for example, be included in the same package, such as a universal Flash storage (UFS) package or an eMMC package. That is, memory system 502 can be implemented and packaged into different types of end electronic products. In one example as shown in FIG. 5, memory controller 506 and a single memory device 504 may be integrated into a memory card 502. Memory card 502 can include a PC card (PCMCIA, personal computer memory card international association), a CF card, a smart media (SM) card, a memory stick, a multimedia card (MMC, RS-MMC, MMCmicro), an SD card (SD, miniSD, microSD, SDHC), a UFS, etc.

Implementations of the subject matter and the actions and operations described in this present disclosure can be implemented in digital electronic circuitry, in tangibly-embodied computer software or firmware, in computer hardware, including the structures disclosed in this present disclosure and their structural equivalents, or in combinations of one or more of them. Implementations of the subject matter described in this present disclosure can be implemented as one or more computer programs, e.g., one or more modules of computer program instructions, encoded on a computer program carrier, for execution by, or to control the operation of, data processing apparatus. The carrier may be a tangible non-transitory computer storage medium. Alternatively, or in addition, the carrier may be an artificially-generated propagated signal, e.g., a machine-generated electrical, optical, or electromagnetic signal, that is generated to encode information for transmission to suitable receiver apparatus for execution by a data processing apparatus. The computer storage medium can be or be part of a machine-readable storage device, a machine-readable storage substrate, a random or serial access memory device, or a combination of one or more of them. A computer storage medium is not a propagated signal.

It is noted that references in the present disclosure to “one embodiment,” “an embodiment,” “an example embodiment,” “some implementations,” “some implementations,” etc., indicate that the embodiment described can include a particular feature, structure, or characteristic, but every embodiment can not necessarily include the particular feature, structure, or characteristic. Moreover, such phrases do not necessarily refer to the same embodiment. Further, when a particular feature, structure or characteristic is described in connection with an embodiment, it would be within the knowledge of a person skilled in the pertinent art to affect such feature, structure or characteristic in connection with other implementations whether or not explicitly described.

In general, terminology can be understood at least in part from usage in context. For example, the term “one or more” as used herein, depending at least in part upon context, can be used to describe any feature, structure, or characteristic in a singular sense or can be used to describe combinations of features, structures or characteristics in a plural sense. Similarly, terms, such as “a,” “an,” or “the,” again, can be understood to convey a singular usage or to convey a plural usage, depending at least in part upon context. In addition, the term “based on” can be understood as not necessarily intended to convey an exclusive set of factors and may, instead, allow for existence of additional factors not necessarily expressly described, again, depending at least in part on context.

It should be readily understood that the meaning of “on,” “above,” and “over” in the present disclosure should be interpreted in the broadest manner such that “on” not only means “directly on” something, but also includes the meaning of “on” something with an intermediate feature or a layer therebetween. Moreover, “above” or “over” not only means “above” or “over” something, but can also include the meaning it is “above” or “over” something with no intermediate feature or layer therebetween (i.e., directly on something).

Further, spatially relative terms, such as “beneath,” “below,” “lower,” “above,” “upper,” and the like, can be used herein for ease of description to describe one element or feature's relationship to another element(s) or feature(s) as illustrated in the figures. The spatially relative terms are intended to encompass different orientations of the device in use or process step in addition to the orientation depicted in the figures. The apparatus can be otherwise oriented (rotated 90 degrees or at other orientations) and the spatially relative descriptors used herein can likewise be interpreted accordingly.

As used herein, the term “substrate” refers to a material onto which subsequent material layers are added. The substrate includes a “top” surface and a “bottom” surface. The top surface of the substrate is typically where a semiconductor device is formed, and therefore the semiconductor device is formed at a top side of the substrate unless stated otherwise. The bottom surface is opposite to the top surface and therefore a bottom side of the substrate is opposite to the top side of the substrate. The substrate itself can be patterned. Materials added on top of the substrate can be patterned or can remain unpatterned. Furthermore, the substrate can include a wide array of semiconductor materials, such as silicon, germanium, gallium arsenide, indium phosphide, etc. Alternatively, the substrate can be made from an electrically noN+ conductive material, such as a glass, a plastic, or a sapphire wafer.

As used herein, the term “layer” refers to a material portion including a region with a thickness. A layer has a top side and a bottom side where the bottom side of the layer is relatively close to the substrate and the top side is relatively away from the substrate. A layer can extend over the entirety of an underlying or overlying structure, or can have an extent less than the extent of an underlying or overlying structure. Further, a layer can be a region of a homogeneous or inhomogeneous continuous structure that has a thickness less than the thickness of the continuous structure. For example, a layer can be located between any set of horizontal planes between, or at, a top surface and a bottom surface of the continuous structure. A layer can extend horizontally, vertically, and/or along a tapered surface. A substrate can be a layer, can include one or more layers therein, and/or can have one or more layer thereupon, thereabove, and/or therebelow. A layer can include multiple layers. For example, an interconnect layer can include one or more conductive and contact layers (in which contacts, interconnect lines, and/or vertical interconnect accesses (VIAs) are formed) and one or more dielectric layers.

As used herein, the term “nominal/nominally” refers to a desired, or target, value of a characteristic or parameter for a component or a process step, set during the design phase of a product or a process, together with a range of values above and/or below the desired value. As used herein, the range of values can be due to slight variations in manufacturing processes or tolerances. As used herein, the term “about” indicates the value of a given quantity that can vary based on a particular technology node associated with the subject semiconductor device. Based on the particular technology node, the term “about” can indicate a value of a given quantity that varies within, for example, 10-30% of the value (e.g., .+−.10%, .+−.20%, or .+−.30% of the value).

In the present disclosure, the term “horizontal/horizontally/lateral/laterally” means nominally parallel to a lateral surface of a substrate, and the term “vertical” or “vertically” means nominally perpendicular to the lateral surface of a substrate.

As used herein, the term “3D memory” refers to a three-dimensional (3D) semiconductor device with vertically oriented strings of memory cell transistors (referred to herein as “memory strings,” such as NAND strings) on a laterally-oriented substrate so that the memory strings extend in the vertical direction with respect to the substrate.

The present disclosure provides many different implementations, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include implementations in which the first and second features may be in direct contact, and may also include implementations in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various implementations and/or configurations discussed.

The foregoing description of the specific implementations can be readily modified and/or adapted for various applications. Therefore, such adaptations and modifications are intended to be within the meaning and range of equivalents of the disclosed implementations, based on the teaching and guidance presented herein.

While the present disclosure contains many specific implementation details, these should not be construed as limitations on the scope of what is being claimed, which is defined by the claims themselves, but rather as descriptions of features that may be specific to particular implementations of particular inventions. Certain features that are described in this present disclosure in the context of separate implementations can also be implemented in combination in a single embodiment. Conversely, various features that are described in the context of a single embodiment can also be implemented in multiple implementations separately or in any suitable sub-combination. Moreover, although features may be described above as acting in certain combinations and even initially be claimed as such, one or more features from a claimed combination can in some cases be excised from the combination, and the claim may be directed to a sub-combination or variation of a sub-combination.

Similarly, while operations are depicted in the drawings and recited in the claims in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system modules and components in the implementations described above should not be understood as requiring such separation in all implementations, and it should be understood that the described program components and systems can generally be integrated together in a single software product or packaged into multiple software products.

Particular implementations of the subject matter have been described. Other implementations also are within the scope of the following claims. For example, the actions recited in the claims can be performed in a different order and still achieve desirable results. As one example, the processes depicted in the accompanying figures do not necessarily require the particular order shown, or sequential order, to achieve desirable results. In some cases, multitasking and parallel processing may be advantageous.

The breadth and scope of the present disclosure should not be limited by any of the above-described exemplary implementations, but should be defined only in accordance with the following claims and their equivalents.

What is claimed is:

1. A semiconductor device, comprising:
at least one array region;
at least one connection region; and
a protection structure surrounding the at least one array region and the at least one connection region, wherein the protection structure has a surface comprising a series of curved portions connected together.

2. The semiconductor device of claim 1, wherein the protection structure extends along a first direction, and the at least one array region is adjacent to the at least one connection region in a second direction perpendicular to the first direction, and
wherein the semiconductor device comprises a stack of conductive layers and insulating layers alternating with each other along the first direction.

3. The semiconductor device of claim 2, wherein the conductive layers and the insulating layers in the stack are located along the first direction within a range defined by a length of the protection structure along the first direction.

4. The semiconductor device of claim 2, wherein the protection structure extends from a first side of the semiconductor device to a second side the semiconductor device along the first direction, the first side and the second side being opposite to each other along the first direction.

5. The semiconductor device of claim 2, wherein the protection structure comprises segments that are connected and enclose the at least one array region and the at least one connection region in a plane perpendicular to the first direction.

6. The semiconductor device of claim 5, wherein the segments comprise:
a first segment and a second segment that each extend along the second direction; and
a third segment and a fourth segment that each extend along a third direction perpendicular to the first direction and the second direction.

7. The semiconductor device of claim 5, wherein a cross section of at least one of the segments has a shape of partial circles arranged in a line and connected together, and
wherein the cross section is perpendicular to the first direction.

8. The semiconductor device of claim 1, wherein the protection structure comprises dielectric portions and a conductive portion between the dielectric portions, the conductive portion being in contact with the dielectric portions, and
wherein at least one of the dielectric portions comprises the surface.

9. The semiconductor device of claim 8, further comprises: a gate line structure, channel structures, and a semiconductor layer connected to the gate line structure and the channel structures,
wherein the conductive portion of the protection structure comprises a conductive structure exposed from a surface of the semiconductor device, and the conductive structure is isolated from the semiconductor layer by a dielectric material.

10. A method, comprising:
providing a semiconductor structure comprising at least one array region and at least one connection region; and
forming a seal ring structure surrounding the at least one array region and the at least one connection region, wherein the seal ring structure has a surface comprising a series of curved portions connected together.

11. The method of claim 10, wherein providing the semiconductor structure comprises:
providing the semiconductor structure comprising a substrate and a stack of sacrificial layers and insulating layers alternating with each other along a first direction; and
wherein forming the seal ring structure comprises:
forming gate line holes, channel holes, and seal ring holes extending through the stack and into the substrate along the first direction, wherein the seal ring holes surround the gate line holes and the channel holes;
forming seal ring trenches and one or more gate line trenches by expanding the seal ring holes and the gate line holes, wherein the seal ring trenches are connected and enclose the one or more gate line trenches; and
forming the seal ring structure in the connected seal ring trenches, wherein the surface of the seal ring structure is non-flat.

12. The method of claim 11, wherein:
the stack comprises one or more decks; and
the gate line holes, the channel holes, and the seal ring holes in at least one of the one or more decks are formed by a same etching process.

13. The method of claim 11, wherein:
the gate line holes comprise one or more groups of gate line holes, each group of the one or more groups of gate line holes are arranged along a second direction perpendicular to the first direction or a third direction perpendicular to the first direction and the second direction, and
the seal ring holes comprise groups of seal ring holes, each group of the groups of seal ring holes are arranged along the second direction or the third direction.

14. The method of claim 13, wherein one of the one or more gate line trenches comprises expanded gate line holes formed from a corresponding group of the one or more groups of gate line holes, and the expanded gate line holes are connected with each other along a corresponding one of the second direction and the third direction, and
wherein one of the seal ring trenches comprises expanded seal ring holes formed from a corresponding group of the groups of seal ring holes, and the expanded seal ring holes are connected with each other along a corresponding one of the second direction and the third direction.

15. The method of claim 14, wherein:
one of the expanded seal ring holes comprises a body portion above the substrate and a bottom portion in the substrate; and
a size of a cross section of the bottom portion is smaller than a size of a cross section of the body portion.

16. The method of claim 11, further comprising:
forming channel structures in the channel holes;
forming conductive layers between the insulating layers by depositing at least one conductive material into the one or more gate line trenches; and
forming one or more gate line structures in the one or more gate line trenches.

17. The method of claim 16, wherein forming the seal ring structure in the connected seal ring trenches comprises:
forming a first dielectric portion, a second dielectric portion, and a dielectric bottom layer in the connected seal ring trenches by depositing a dielectric material into the connected seal ring trenches, wherein the first dielectric portion is in contact with a first sidewall of the connected seal ring trenches, the second dielectric portion is in contact with a second sidewall of the connected seal ring trenches, the dielectric bottom layer is in contact with a bottom of the connected seal ring trenches, and the first dielectric portion is connected to the second dielectric portion by the dielectric bottom layer; and
forming a conductive portion by filling a conductive material between the first dielectric portion and the second dielectric portion.

18. The method of claim 17, wherein:
the semiconductor structure further comprises a polysilicon layer between the stack and the substrate; and
a bottom of the conductive portion is above the polysilicon layer along the first direction.

19. The method of claim 18, further comprising:
removing the substrate and the dielectric bottom layer;
forming a conductive structure connected to the conductive portion, wherein the conductive structure is exposed from a surface of the semiconductor structure; and
forming a semiconductor layer connected to the one or more gate line structures and the channel structures, wherein the semiconductor layer comprises a polysilicon material.

20. A memory system, comprising:
a memory device; and
a memory controller coupled to the memory device and configured to control the memory device,
wherein the memory device comprises:
at least one array region;
at least one connection region; and
a protection structure surrounding the at least one array region and the at least one connection region, wherein the protection structure has a surface comprising a series of curved portions connected together.
